(19) United States
(12) Patent Application Publication
(10) Pub. No.: US 2021/0318395 A1
(43) Pub. Date: Oct. 14, 2021

(54) MAGNETORESISTIVE ELEMENT

(71) Applicant: SONY SEMICONDUCTOR SOLUTIONS CORPORATION, Kanagawa (JP)

(72) Inventors: Makoto UEKI, Kumamoto (JP); Katsumi SUEMITSU, Kumamoto (JP)

(73) Assignee: SONY SEMICONDUCTOR SOLUTIONS CORPORATION, Kanagawa (JP)

(21) Appl. No.: 17/287,578

(22) PCT Filed: Oct. 29, 2019
(86) PCT No.: PCT/JP2019/042295

§ 371 Date: Apr. 22, 2021

(30) Foreign Application Priority Data
Nov. 6, 2018 (JP) 2018-208760

(51) Int. Cl. G01R 33/09; H01L 43/10; H01L 43/08; H01L 43/02; G11C 11/16

(52) U.S. Cl. CPC G01R 33/093; H01L 43/10; G11C 11/161; H01L 43/02; H01L 43/08

(57) ABSTRACT

A magnetoresistive element of the present disclosure has at least a layered structure composed of a magnetization fixed layer, an intermediate layer and a storage layer, wherein a metal layer is formed on or above the layered structure; an orthogonal projection image of the layered structure with respect to the metal layer is contained in the metal layer; and assuming that an oxide formation Gibbs energy of a metal atom constituting the metal layer at a temperature T (° C.) of 0° C. or higher and 400° C. or lower is E_{Gib-0}(T), a minimum Gibbs energy among oxide formation Gibbs energies of metal atoms constituting the magnetization fixed layer and the storage layer at the temperature T is E_{Gib-1}(T), and a maximum Gibbs energy among oxide formation Gibbs energies of metal atoms constituting the intermediate layer at the temperature T is E_{Gib-2}(T), E_{Gib-0}(T)<E_{Gib-1}(T) and/or E_{Gib-2}(T)≤E_{Gib-0}(T) is satisfied.

### TECHNICAL FIELD

The present disclosure relates to a magnetoresistive element.

### BACKGROUND ART

Since a MRAM (Magnetic Random Access Memory) stores data on the basis of a magnetization direction of a magnetic material, the memory can be rewritten at high speed and almost infinitely (10¹⁵ times or more), and such memory has already been used in the fields of industrial automation, aircrafts, and the like. Due to high-speed operation and high reliability thereof, MRAM is expected to find application to code storage and working memory in the future, but in reality, it is difficult to reduce power consumption and increase capacity of the memory. This is an essential problem due to the recording principle of MRAM, that is, the method of reversing the magnetization by a current magnetic field generated from wiring. As a method for solving this problem, a recording method that does not depend on the current magnetic field, that is, a magnetization reversal method has been studied, and in this approach, a magnetoresistive element composed of a spin injection type magnetoresistance effect element employing magnetization reversal by spin injection (STT-MRAM, Spin Transfer Torque based Magnetic Random Access Memory) has attracted attention (see, for example, JP 2013-008868 A).

Magnetization reversal by spin injection is a phenomenon in which electrons that have passed through a magnetic material and have been spin-polarized are injected into another magnetic material, causing magnetization reversal in the other magnetic material. As a result of using magnetization reversal by spin injection, a magnetoresistive element composed of a spin injection type magnetoresistance effect element is superior to a MRAM, in which magnetization reversal is performed based on an external magnetic field, in that the write current does not increase even if the element becomes finer, scaling is possible because the write current value decreases in proportion to the element volume, and the cell area can be reduced. Another advantage is that since a word wire for generating a recording current magnetic field, which is required for MRAM, is not needed, the device structure and cell structure are simplified. A magnetoresistive element composed of a spin injection type magnetoresistance effect element has, for example, a layered structure composed of a magnetization fixed layer, an intermediate layer and a storage layer.

### CITATION LIST

### Patent Literature

[PTL 1]

JP 2013-008868 A

### SUMMARY

### Technical Problem

In the manufacturing process of a magnetoresistive element composed of such a spin-injection type magnetoresistance effect element, the layered structure of the magnetoresistive element in the process of being manufactured is often exposed to an oxidizing atmosphere or a reducing atmosphere. As a result, various layers constituting the layered structure of the magnetoresistive element are oxidized or reduced. When such a phenomenon occurs in the layered structure, various problems such as deterioration of information retention characteristics of the magnetoresistive element, an increase in the information writing voltage and the information rewriting voltage, and variation in the resistance value occur.

Therefore, an object of the present disclosure is to provide a magnetoresistive element having stable characteristics.

### Solution to Problem

A magnetoresistive element according to the first mode of the present disclosure for achieving the above object

has at least a layered structure composed of a magnetization fixed layer, an intermediate layer and a storage layer, wherein
a metal layer is formed on or above the layered structure;
an orthogonal projection image of the layered structure with respect to the metal layer is contained in the metal layer; and
assuming that an oxide formation Gibbs energy of a metal atom constituting the metal layer at a temperature T (° C.) of 0° C. or higher and 400° C. or lower is E_{Gib-0}(T), and a minimum Gibbs energy among oxide formation Gibbs energies of metal atoms constituting the magnetization fixed layer and the storage layer at the temperature T is E_{Gib-1}(T),

E_{Gib-0}(T)<E_{Gib-1}(T) (1)

is satisfied.

A magnetoresistive element according to the second mode of the present disclosure for achieving the above object

has at least a layered structure composed of a magnetization fixed layer, an intermediate layer and a storage layer, wherein
a metal layer is formed on or above the layered structure;
an orthogonal projection image of the layered structure with respect to the metal layer is contained in the metal layer; and
assuming that an oxide formation Gibbs energy of a metal atom constituting the metal layer at a temperature T (° C.) of 0° C. or higher and 400° C. or lower is E_{Gib-0}(T), and a maximum Gibbs energy among oxide formation Gibbs energies of metal atoms constituting the intermediate layer at the temperature T is E_{Gib-2}(T),

E_{Gib-2}(T)≤E_{Gib-0}(T) (2)

is satisfied.

### BRIEF DESCRIPTION OF DRAWINGS

FIG. 1 is a schematic partial cross-sectional view of a magnetoresistive element of Embodiment 1.

FIG. 2 is an equivalent circuit diagram of the magnetoresistive element of Embodiment 1.

FIGS. 3A and 3B are conceptual diagrams of a spin-injection magnetoresistance effect element to which spin-injection magnetization reversal has been applied.

FIGS. 4A and 4B are conceptual diagrams of a spin-injection magnetoresistance effect element to which spin-injection magnetization reversal has been applied.

FIGS. 5A, 5B, and 5C are schematic partial end views of a layered structure and the like for explaining a method for manufacturing the magnetoresistive element of Embodiment 1.

FIGS. 6A, 6B, and 6C are schematic partial end views of a layered structure and the like for explaining a method for manufacturing the magnetoresistive element of Embodiment 1, following FIG. 5C.

FIGS. 7A and 7B are schematic partial end views of a layered structure and the like for explaining a modification example of the method for manufacturing the magnetoresistive element according to Embodiment 1.

FIGS. 8A and 8B are schematic partial end views of a layered structure and the like for explaining a modification example of the method for manufacturing the magnetoresistive element according to Embodiment 1, following FIG. 7B.

FIG. 9 is a schematic partial cross-sectional view of a magnetoresistive element of Embodiment 2.

FIG. 10 is a schematic partial end view of a layered structure and the like for explaining a method for manufacturing the magnetoresistive element of Embodiment 2.

FIG. 11 is a schematic partial end view of the layered structure and the like for explaining the method for manufacturing the magnetoresistive element of Embodiment 2, following FIG. 10.

FIG. 12 is a schematic partial cross-sectional view of a magnetoresistive element of Embodiment 3.

FIG. 13 is a schematic partial end view of a layered structure and the like for explaining a method for manufacturing the magnetoresistive element of Embodiment 3.

FIG. 14 is a schematic partial end view of the layered structure and the like for explaining the method for manufacturing the magnetoresistive element of Embodiment 3, following FIG. 13.

FIG. 15 is a schematic partial cross-sectional view of the magnetoresistive element of Embodiment 4.

FIG. 16 is a schematic partial end view of a layered structure and the like for explaining a method for manufacturing the magnetoresistive element of Embodiment 4 shown in FIG. 15.

FIG. 17 is a schematic partial end view of the layered structure and the like for explaining the method for manufacturing the magnetoresistive element of Embodiment 4 shown in FIG. 15, following FIG. 16.

FIGS. 18A, 18B, and 18C are schematic partial cross-sectional views of a layered structure and the like of a modification example of the magnetoresistive element of Embodiment 4.

FIGS. 19A, 19B, and 19C are schematic partial end views of the layered structure and the like for explaining a method for manufacturing the modification example of the magnetoresistive element of Embodiment 4 shown in FIG. 18C.

FIG. 20 is a schematic partial cross-sectional view of another modification example of the magnetoresistive element of Embodiment 4.

FIGS. 21A and 21B are a schematic perspective view showing a cut-out part of a composite magnetic head of Embodiment 5 and a schematic cross-sectional view of the composite magnetic head of Embodiment 5, respectively.

FIG. 22 is a schematic partial cross-sectional view of a modification example of the magnetoresistive element of Embodiment 1.

FIG. 23 is a conceptual diagram of the magnetoresistive element of the present disclosure.

### DESCRIPTION OF EMBODIMENTS

Hereinafter, the present disclosure will be described based on embodiments with reference to the drawings, but the present disclosure is not limited to the embodiments, and various numerical values and materials in the embodiments are exemplary. The description will be given in the following order.
1. Description of the magnetoresistive element according to the first and second modes of the present disclosure and general information.
2. Embodiment 1 (Magnetoresistance elements according to the first and second modes of the present disclosure)
3. Embodiment 2 (Modification of Embodiment 1)
4. Embodiment 3 (Another modification of Embodiment 1)
5. Embodiment 4 (Modifications of Embodiments 1 to 3)
6. Embodiment 5 (Application example of magnetoresistive elements of Embodiments 1 to 4)
7. Other

Description of Magnetoresistive Elements According to First and Second Modes of the Present Disclosure, and General Information

The magnetoresistive element according to the first mode of the present disclosure can be in a form in which assuming that a maximum Gibbs energy among oxide formation Gibbs energies of metal atoms constituting the intermediate layer at the temperature T is E_{Gib-2}(T),

E_{Gib-2}(T)≤E_{Gib-0}(T) (2)

is satisfied.

The magnetoresistive element according to the first mode of the present disclosure including the above preferred form, or the magnetoresistive element according to the second mode of the present disclosure can be in a form in which the metal layer includes at least one metal atom selected from the group consisting of a titanium (Ti) atom, an aluminum (Al) atom, and a magnesium (Mg) atom.

Furthermore, the magnetoresistive elements according to the first and second modes of the present disclosure including the preferred form described above can be in a form in which a metal atom constituting the magnetization fixed layer and the storage layer includes a cobalt (Co) atom, or an iron (Fe) atom, or a cobalt atom and an iron atom (Co—Fe). In other words, a form is possible in which a metal atom constituting the magnetization fixed layer and the storage layer includes at least a cobalt (Co) atom or an iron (Fe) atom. That is, a form is possible in which the magnetization fixed layer and the storage layer are configured of a metal material (alloy, compound) composed of at least cobalt (Co) or iron (Fe). Here, a form is possible in which the cobalt (Co) atom or the iron (Fe) atom, or the cobalt atom and the iron atom (Co—Fe) constituting the magnetization fixed layer are included at 50 atomic % or more, preferably 70 atomic % or more in the magnetization fixed layer. Further, a form is possible in which the cobalt (Co) atom or the iron (Fe) atom, or the cobalt atom and the iron atom (Co—Fe) constituting the magnetization fixed layer are included at 50 atomic % or more, preferably 70 atomic % or more in the storage layer. Alternatively, as a metal atom constituting the magnetization fixed layer and/or storage layer, nickel (Ni), platinum (Pt), palladium (Pd), rhodium (Rh), terbium (Tb), manganese (Mn), and iridium (Ir) can be mentioned.

Alternatively, the magnetoresistive element according to the first mode and the second mode of the present disclosure including the various preferred forms and configurations described above can be in a form in which the storage layer is configured of a metal material (alloy, compound) composed of cobalt, iron and nickel, or of a metal material (alloy, compound) composed of cobalt, iron, nickel, and boron. Alternatively, a material constituting the storage layer can be exemplified by alloys of ferromagnetic materials such as nickel (Ni), iron (Fe), and cobalt (Co) (for example, Co—Fe, Co—Fe—B, Co—Fe—Ni, Fe—Pt, Ni—Fe, Fe—B, Co—B, and the like), or alloys obtained by adding gadolinium (Gd) to these alloys. Furthermore, in a perpendicular magnetization type, a heavy rare earth element such as terbium (Tb), dysprosium (Dy), and holmium (Ho) may be added to the alloy in order to further increase a perpendicular magnetic anisotropy, or an alloy containing these may be layered. The storage layer essentially can have any crystallinity, and the storage layer may be polycrystalline, monocrystalline, or amorphous. Further, the storage layer can have a single-layer configuration, a layered configuration in which a plurality of different ferromagnetic material layers described above is layered, or a layered structure in which a ferromagnetic material layer and a non-magnetic material layer are layered. Since the proportion of the gadolinium (Gd) and heavy rare earths as atoms occupying the storage layer is small, it is not necessary to satisfy the formula (1). Alternatively, the minimum Gibbs energy among oxide formation Gibbs energies of metal atoms constituting the magnetization fixed layer and the storage layer and taking 5 atomic % or more is E_{Gib-1}(T).

It is also possible to add a non-magnetic element to the material constituting the storage layer. By adding a non-magnetic element, effects such as improvement of heat resistance by preventing diffusion, increase of magnetoresistance effect, and increase of dielectric strength due to planarization can be obtained. As a non-magnetic element to be added, B, C, N, O, F, Li, Mg, Si, P, Ti, V, Cr, Mn, Ni, Cu, Ge, Nb, Ru, Rh, Pd, Ag, Ta, Ir, Pt, Au, Zr, Hf, W, Mo, Re, and Os can be mentioned. Since the proportion of the atom corresponding to the non-magnetic element as an atom occupying the storage layer is small, it is not necessary to satisfy the formula (1). Alternatively, the minimum Gibbs energy among oxide formation Gibbs energies of metal atoms constituting the magnetization fixed layer and the storage layer and taking 5 atomic % or more is E_{Gib-1}(T).

Furthermore, as a storage layer, ferromagnetic material layers having different compositions can be layered. Alternatively, it is also possible to layer a ferromagnetic material layer and a soft magnetic material layer, or to layer a plurality of ferromagnetic material layers with a soft magnetic material layer or a non-magnetic material layer interposed therebetween. In particular, in the case of a configuration in which a plurality of ferromagnetic material layers such as an Fe layer, a Co layer, an Fe—Ni alloy layer, a Co—Fe alloy layer, a Co—Fe—B alloy layer, an Fe—B alloy layer, and a Co—B alloy layer is layered with a non-magnetic layer being interposed therebetween, the relationship of magnetic strength between the ferromagnetic material layers can be adjusted, so that the magnetization reversal current in the spin injection type magnetoresistance effect element can be prevented from increasing. As a material for the non-magnetic layer Ru, Os, Re, Ir, Au, Ag, Cu, Al, Bi, Si, B, C, Cr, Ta, Pd, Pt, Zr, Hf, W, Mo, Nb, V, or alloys thereof can be mentioned. Since the proportion of the atom constituting the non-magnetic material layer as an atom occupying the storage layer is small, it is not necessary to satisfy the formula (1). Alternatively, the minimum Gibbs energy among oxide formation Gibbs energies of metal atoms constituting the magnetization fixed layer and the storage layer and taking 5 atomic % or more is E_{Gib-1}(T).

The thickness of the storage layer can be exemplified by 0.5 nm to 30 nm, and the thickness of the magnetization fixed layer can be exemplified by 0.5 nm to 30 nm.

The magnetization fixed layer can be in a form having a layered ferri structure (also referred to as a layered ferri-pin structure) in which at least two magnetic material layers are layered. Specifically, the layered ferri structure is a layered structure with antiferromagnetic coupling, that is, a structure in which interlayer exchange coupling of two magnetic material layers (a reference layer and a fixed layer) becomes antiferromagnetic, which is also called synthetic antiferromagnetic coupling (SAF: Synthetic Antiferromagnet) indicating a structure in which interlayer exchange coupling of the two magnetic material layers (one magnetic material layer is sometimes called a “reference layer”, and the other magnetic material layer that constitutes the layered ferri structure is sometimes called a “fixed layer”) is antiferromagnetic or ferromagnetic depending on a thickness of a non-magnetic layer provided between the two magnetic material layers. Such structure has been reported in, for example, S. S. Parkin et al., Physical Review Letters, 7 May, pp. 2304-2307 (1990). Here, a magnetization direction of the reference layer is a magnetization direction serving as a reference for information to be stored in the storage layer. One magnetic material layer (the reference layer) constituting the layered ferri structure is located on the storage layer side. In this case,

one of the magnetic material layers (for example, the reference layer) constituting the layered ferri structure includes at least one element selected from the group consisting of iron (Fe), cobalt (Co) and nickel (Ni), or includes at least one element selected from the group consisting of iron (Fe), cobalt (Co), and nickel (Ni) and also includes (B), and can be specifically exemplified by a Co—Fe alloy, a Co—Fe—Ni alloy, a Ni—Fe alloy, and a Co—Fe—B alloy, and by a layered structure such as Fe layer/Pt layer, Fe layer/Pd layer, Co layer/Pt layer, Co layer/Pd layer, Co layer/Ni layer, and Co layer/Rh layer. Magnetic properties of these materials can be adjusted and various physical properties thereof such as crystal structure, crystallinity, and material stability can be adjusted by adding a non-magnetic element such as Ag, Cu, Au, Al, Si, Bi, Ta, B, C, O, N, Pd, Pt, Zr, Ta, Hf, Ir, W, Mo, Nb, V, Ru, and Rh thereto, and

the other magnetic material layer (for example, the fixed layer) constituting the layered ferri structure can be composed of a material including at least one element selected from the group consisting of iron (Fe), cobalt (Co), nickel (Ni) and manganese (Mn) (referred to as “element-A” for convenience) and at least one element selected from the group consisting of platinum (Pt), palladium (Pd), nickel (Ni), iridium (Ir) and rhodium (Rh) (however, an element different from the element-A, referred to as “element-B” for convenience) as main components. Further, as a material constituting the non-magnetic layer, ruthenium (Ru), an alloy thereof, and a ruthenium compound can be mentioned, or Os, Re, Ir, Au, Ag, Cu, Al, Bi, Si, B, C, Cr, Ta, Pd, Pt, Zr, Hf, W, Mo, Nb, V, Rh and alloys thereof can be mentioned. By adopting a layered ferri structure for the magnetization fixed layer, it is possible to reliably cancel out asymmetry in thermal stability in an information writing direction and to improve stability in spin torque. Since the proportion of the atom corresponding to the non-magnetic element or the atom constituting the non-magnetic element as an atom occupying the magnetization fixed layer is small, it is not necessary to satisfy the formula (1). Alternatively, the minimum Gibbs energy among oxide formation Gibbs energies of metal atoms constituting the magnetization fixed layer and the storage layer and taking 5 atomic % or more is E_{Gib-1}(T).

In addition, the magnetization fixed layer can have a configuration in which the direction of magnetization thereof is fixed by only the ferromagnetic layer or by using the antiferromagnetic coupling between the antiferromagnetic layer and the ferromagnetic layer. As the antiferromagnetic material, an Fe—Mn alloy, an Fe—Pt alloy, a Ni—Mn alloy, a Pt—Mn alloy, a Pt—Cr—Mn alloy, an Ir—Mn alloy, a Rh—Mn alloy, and a Co—Pt alloy, cobalt oxide, nickel oxide (NiO), and iron oxide (Fₑ₂O₃) can be mentioned. Alternatively, magnetic properties of these materials can be adjusted and various physical properties thereof such crystal structure, crystallinity, and material stability can be adjusted by adding a non-magnetic element such as Ag, Cu, Au, Al, Si, Bi, Ta, B, C, O, N, Pd, Pt, Zr, Ta, Hf, Ir, W, Mo, Nb, V, Ru, and Rh thereto. Since the proportion of the atom corresponding to the non-magnetic element as an atom occupying the magnetization fixed layer is small, it is not necessary to satisfy the formula (1). Alternatively, the minimum Gibbs energy among oxide formation Gibbs energies of metal atoms constituting the magnetization fixed layer and the storage layer and taking 5 atomic % or more is E_{Gib-1}(T).

However, the magnetization fixed layer is not limited to the form having a layered ferri structure. It may also be configured as a magnetization fixed layer composed of one layer and functioning as a reference layer. As a material constituting such a magnetization fixed layer, a material (ferromagnetic material) constituting the below-described storage layer can be mentioned, or the magnetization fixed layer (reference layer) can be configured to be composed of a layered body of a Co layer and a Pt layer, a layered body of a Co layer and a Pd layer, a layered body of a Co layer and a Ni layer, a layered body of a Co layer and a Tb layer, a Co—Pt alloy layer, a Co—Pd alloy layer, a Co—Ni alloy layer, a Co—Fe alloy layer, a Co—Tb alloy layer, a Co layer, an Fe layer, or a Co—Fe—B alloy layer, or magnetic properties of these materials can be adjusted and various physical properties thereof such as crystal structure, crystallinity, and material stability can be adjusted by adding a non-magnetic element such as Ag, Cu, Au, Al, Si, Bi, Ta, B, C, O, N, Pd, Pt, Zr, Ta, Hf, Ir, W, Mo, Nb, V, Ru, and Rh thereto, and furthermore, preferably, the magnetization fixed layer (reference layer) can be configured to be composed of a Co—Fe—B alloy layer. Since the proportion of the atom corresponding to the non-magnetic element as an atom occupying the magnetization fixed layer is small, it is not necessary to satisfy the formula (1). Alternatively, the minimum Gibbs energy among oxide formation Gibbs energies of metal atoms constituting the magnetization fixed layer and the storage layer and taking 5 atomic % or more is E_{Gib-1}(T).

Since the magnetization direction of the magnetization fixed layer is a reference for information, the magnetization direction should not be changed by recording or reading of information, but the magnetization direction does not necessarily have to be fixed to a specific direction, and a configuration and a structure in which the magnetization direction is less likely to change than that in the storage layer may be obtained by increasing a coercive force with respect to that in the storage layer, increasing the film thickness, or increasing a magnetic damping constant.

Further, the magnetoresistive element according to the first mode and second mode of the present disclosure including the preferred forms described above can have a form in which the metal atom constituting the intermediate layer is a magnesium (Mg) atom or an aluminum (Al) atom.

Alternatively, in the magnetoresistive element according to the first mode and second mode of the present disclosure including the preferred forms described above, the intermediate layer is preferably composed of a non-magnetic material. That is, in the spin injection type magnetoresistive element, the intermediate layer that constitutes a layered structure having a TMR (Tunnel Magnetoresistance) effect is preferably an insulating material and is composed of a non-magnetic material. Configuring a layered structure having a TMR effect of a magnetization fixed layer, an intermediate layer and a storage layer refers to a structure in which an intermediate layer composed of a non-magnetic material film functioning as a tunnel insulating film is sandwiched between a magnetization fixed layer composed of a magnetic material and a storage layer composed of a magnetic material. Here, as a material that is an insulating material and a non-magnetic material, various insulating materials dielectric materials, and semiconductor materials such as magnesium oxide (MgO), magnesium nitride, magnesium fluoride, aluminum oxide (AlO_{X}), aluminum nitride (AlN), silicon oxide (SiO_{X}), silicon nitride (SiN), TiO₂, Cr₂O₃, Ge, NiO, CdO_{X}, HfO₂, Ta₂O₅, Bi₂O₃, CaF, SrTiO₂, AlLaO₃, Mg—Al₂—O, Al—N—O, BN, and ZnS can be mentioned. The area resistance value of the intermediate layer composed of the insulating material is preferably about several tens of Ω·μm² or less. Where the intermediate layer is configured of magnesium oxide (MgO), it is desirable that the MgO layer be crystallized, and it is more desirable that the intermediate layer have crystal orientation in the (001) direction. Further, where the intermediate layer is configured of magnesium oxide (MgO), the thickness thereof is preferably 1.5 nm or less.

An intermediate layer that is an insulating material and is configured of a non-magnetic material can be obtained, for example, by oxidizing or nitriding a metal film formed by a sputtering method. More specifically, where aluminum oxide (AlO_{X}) or magnesium oxide (MgO) is used as the insulating material constituting the intermediate layer, examples of suitable method include a method of oxidizing, in the atmosphere, aluminum or magnesium formed by a sputtering method, a method of plasma-oxidizing aluminum or magnesium formed by the sputtering method, a method of IPC plasma-oxidizing aluminum or magnesium formed by the sputtering method, a method of naturally oxidizing, in oxygen, aluminum or magnesium formed by the sputtering method, a method of oxidizing aluminum and magnesium formed by the sputtering method with oxygen radicals, a method of irradiating aluminum and magnesium formed by the sputtering method with ultraviolet radiation while naturally oxidizing in oxygen, a method of forming a film of aluminum or magnesium by a reactive sputtering method, and a method of forming a film of aluminum oxide (AlO_{X}) or magnesium oxide (MgO) by the sputtering method.

Further, the magnetoresistive element according to the first mode and second modes of the present disclosure including the preferable forms described above can have a form in which the metal atom constituting the metal layer is contained in the metal layer at 60 atomic % or more, and preferably at 80 atomic % or more. The remaining atoms occupying the metal layer can be exemplified by nitrogen (N), carbon (C), oxygen (O), tungsten (W), and tantalum (Ta).

Further, the magnetoresistive element according to the first mode and second modes of the present disclosure including the preferable forms described above can have a form in which the thickness of the metal layer is 1×10⁻⁸ m or more, preferably 2×10⁻⁸ m or more, whereby a metal layer having a desired volume can be obtained.

Further, the magnetoresistive element according to the first mode and second modes of the present disclosure including the preferable forms described above can have a form in which the side surface of the layered structure is covered with a sidewall. In this case, assuming that an oxide formation Gibbs energy of a metal atom constituting the sidewall at the temperature T is E_{Gib-SW}(T),

E_{Gib-2}(T)≤E_{Gib-SW}(T)<E_{Gib-1}(T) (3)

is satisfied. Furthermore, in these cases, in a possible form, the atom constituting the sidewall is at least one atom selected from the group consisting of titanium (Ti), aluminum (Al), magnesium (Mg), and silicon (Si). Furthermore, in these cases, in a possible form, at least a part of the sidewall is covered with a metal layer. The sidewall is composed of an oxide.

Further, the magnetoresistive element according to the first mode and second modes of the present disclosure including the preferable forms described above can have a configuration in which

the layered structure is surrounded by an insulating layer;
a connection portion connected to the layered structure is formed on or above the layered structure; and
the metal layer is formed on an inner wall of the connection portion.

In this case, a configuration is possible in which the connection portion is configured of a metal layer and a contact hole portion, and further, assuming that the area of the facing surface of the layered structure facing the metal layer is Si, and the area of the facing surface of the metal layer facing the structure is S₂, it is preferable that

S₂/S₁≥1

desirably

S₂/S₁≥2

is satisfied. The upper limit of S₂/S₁ can be exemplified, but is not limited to, 30.

Alternatively, in this case, a configuration is possible in which the connection portion is configured of a metal layer and a part of the wiring having a damascene structure, and further, assuming that the length of the portion of the layered structure facing the metal layer in a virtual plane orthogonal to the extension direction of the wiring is L₁, and the length of the portion of the metal layer facing the layered structure in the virtual plane is L₂, it is preferable that

L₂/L₁≥1

desirably

L₂/L₁≥2

is satisfied. The upper limit of L₂/L₁ can be exemplified, but is not limited to, 10.

Alternatively, in this case, a configuration is possible in which

the layered structure is surrounded by an insulating layer;
a metal layer is formed on or above the layered structure and is connected to the layered structure; and
a wiring layer is formed on the metal layer, and further, assuming that the length of the portion of the layered structure facing the metal layer in a virtual plane orthogonal to the extension direction of the wiring is Li, and the length of the portion of the metal layer facing the layered structure in the virtual plane is L₂, it is preferable that

L₂/L₁≥1

desirably

L₂/L₁≥2

is satisfied. The upper limit of L₂/L₁ can be exemplified, but is not limited to, 100.

The magnetoresistive element according to the first mode and second mode of the present disclosure including various preferable forms and configurations described above (hereinafter, may be collectively referred to as “magnetoresistive element and the like of the present disclosure”) can have a form in which, as mentioned hereinabove, the magnetization direction of the storage layer changes according to the information to be stored, and in the storage layer, the easy axis of magnetization is parallel to the layering direction of the layered structure (that is, the form of a vertical magnetization type). In this case, the element may be composed of a spin injection type magnetoresistive element of a vertical magnetization system, and further, in these cases, the first surface of the layered structure is in contact with the first electrode, the second surface of the layered structure is in contact with the second electrode, and a current (also called magnetization reversal current or spin-polarized current, which is a write current) flows between the first electrode and the second electrode, whereby a form can be obtained in which information is stored in the storage layer. That is, by allowing a magnetization reversal current to flow in the layering direction of the layered structure, a form can be obtained in which the magnetization direction of the storage layer is changed, and information is recorded in the storage layer.

The magnetization fixed layer may constitute the first surface of the layered structure, or the storage layer may constitute the first surface of the layered structure.

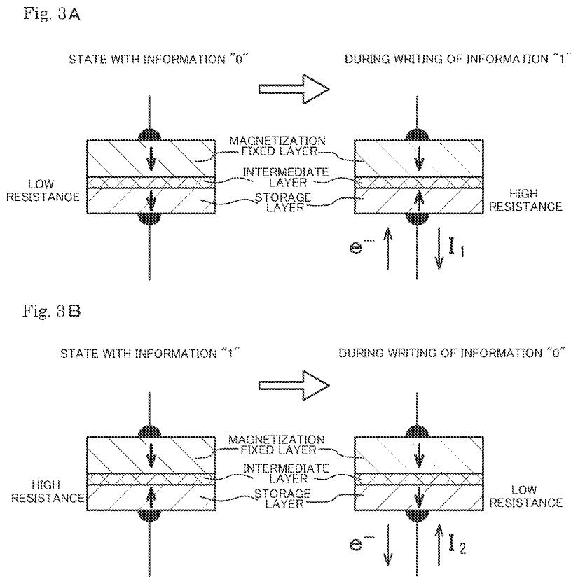

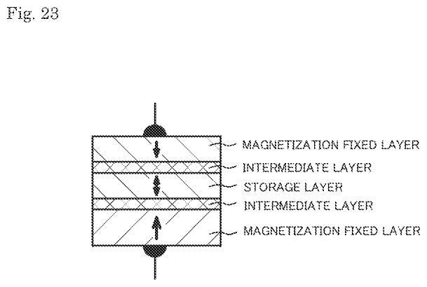

As described above, the magnetoresistive element and the like of the present disclosure, can have a structure in which a layered structure having a TMR effect is configured of a layered structure composed of a storage layer, an intermediate layer, and a magnetization fixed layer. For example, as shown in the conceptual diagram in FIG. 3B, where a magnetization reversal current flows from the storage layer to the magnetization fixed layer in an antiparallel magnetization state, the magnetization of the storage layer is reversed by a spin torque acting due to the injection of electrons from the magnetization fixed layer into the storage layer, and the magnetization direction of the storage layer, the magnetization direction of the magnetization fixed layer (specifically, the reference layer), and the magnetization direction of the storage layer are arranged in parallel. Meanwhile, for example, as shown in the conceptual diagram in FIG. 3A, where a magnetization reversal current flows from the magnetization fixed layer to the storage layer in a parallel magnetization state, the magnetization of the storage layer is reversed by a spin torque acting due to the flow of electrons from the storage layer to the magnetization fixed layer, and the magnetization direction of the storage layer, the magnetization direction of the magnetization fixed layer (specifically, the reference layer), and the magnetization direction of the storage layer are in an antiparallel magnetization state. Alternatively, as shown in the conceptual diagram in FIG. 23, a structure may be such that a layered structure having a TMR effect is configured of a magnetization fixed layer, an intermediate layer, a storage layer, an intermediate layer, and a magnetization fixed layer. In such a structure, it is necessary to create a difference in the change of magnetic reluctance between the two intermediate layers located above and below the storage layer.

From the viewpoints of ensuring easy processing and uniformity in the direction of easy axis of magnetization of the storage layer, it is desirable that the three-dimensional shape of the layered structure be a cylindrical shape or a columnar shape, but such shape is not limiting, and the shape can be a triangular prism, a quadrangular prism, a hexagonal prism, an octagonal prism, and the like (including those having rounded sides or ridges), or an elliptical cylinder. From the viewpoint of easily reversing the direction of magnetization with a low magnetization reversal current, the area of the layered structure is preferably, for example, 0.01 μm² or less. Information is written to the storage layer by setting the direction of magnetization in the storage layer to the first direction (direction parallel to the easy axis of magnetization) or the second direction (direction opposite to the first direction) by allowing a magnetization reversal current to flow in the layered structure from the first electrode to the second electrode, or from the second electrode to the first electrode.

Furthermore, in the magnetoresistive element and the like of the present disclosure including the various preferable forms and configurations described above, the layered structure can have a form having a cap layer on the second surface side in order to prevent mutual diffusion of the atoms constituting the electrodes and connection portions and the atoms constituting the storage layer, reduce contact resistance and prevent oxidation of the storage layer. In this case, a form is possible in which the cap layer is configured of a monolayer structure composed of at least a material selected from the group consisting of hafnium, tantalum, tungsten, zirconia, niobium, molybdenum, titanium, vanadium, chromium, magnesium, ruthenium, rhodium, palladium, and platinum; a monolayer structure composed of oxides such as a magnesium oxide layer, an aluminum oxide layer, a titanium oxide layer, a silicon oxide layer, a Bi₂O₃ layer, a SrTiO₂ layer, an AlLaO₃ layer, an Al—N—O layer, a Mg—Ti—O layer, and a MgAl₂O₄ layer; and a layered structure of at least one material layer selected from the group consisting of hafnium, tantalum, tungsten, zirconia, niobium, molybdenum, titanium, vanadium, chromium, magnesium, ruthenium, rhodium, palladium and platinum and at least one oxide layer selected from the group consisting of MgTiO, MgO, AlO, and SiO (for example, Ru layer/Ta layer).

The various layers described above can be formed by, for example, a physical vapor deposition method (PVD method) exemplified by a sputtering method, an ion beam deposition method, and a vacuum vapor deposition method, and a chemical vapor deposition method (CVD method) exemplified by an ALD (Atomic Layer Deposition) method. Further, these layers can be patterned by a reactive ion etching method (RIE method) or an ion milling method (ion beam etching method). It is preferable to form the various layers continuously in a vacuum apparatus, and it is preferable that patterning be performed thereafter.

The first electrode, second electrode, first wiring, second wiring, wiring layer, and the like may be composed of a layered structure of Ta or TaN, Cu, Al, Au, Pt, Ti, and the like or compounds thereof, or may have a layered structure of a base layer composed of Cr, Ti and the like, and a Cu layer, an Au layer, a Pt layer and the like formed on the base layer. Alternatively, they can also be configured of a monolayer structure of Ta or a compound thereof, or a layered structure of Cu, Ti, and the like or compounds thereof. These electrodes and the like can be formed by, for example, by a PVD method exemplified by a sputtering method.

In the magnetoresistive element and the like of the present disclosure, a selection transistor composed of a field effect transistor is provided below the layered structure, and for example, a form is possible in which a projection image in the extension direction of a second wiring (a bit wire) connected to a second electrode is orthogonal to a projection image in the extension direction of a gate electrode (for example, which also functions as a word line or an address line) constituting the field effect transistor, and a form is also possible in which the projection image in the extension direction of the second wiring (the bit wire) is parallel to the projection image in the extension direction of the gate electrode constituting the field effect transistor. Further, a form is possible in which a projection image in the extension direction of a first wiring (sense wire) connected to a first electrode is parallel to the projection image in the extension direction of the second wiring. In some cases, the selection transistor is not needed.

In the preferred configuration of the magnetoresistive element, as described above, a selection transistor composed of a field effect transistor is further provided below the layered structure, but a more specific configuration, for example, can be exemplified by, but is not limited to, a configuration including:

a selection transistor formed on a semiconductor substrate; and
an interlayer insulating layer covering the selection transistor, wherein
a first electrode is formed on the interlayer insulating layer;
the first electrode is electrically connected to one source/drain region of the selection transistor via a connection hole (or a connection hole and a landing pad or a lower layer wiring) provided in the interlayer insulation layer;
the layered structure is in contact with the first electrode and the second electrode; and
the insulating layer covers the interlayer insulating layer and surrounds the first electrode, the layered structure, and the second electrode.

In some cases, a sidewall is formed between the side surface of the layered structure and the insulating layer.

The selection transistor can be configured of, for example, a well-known MIS type FET or MOS type FET. The connection hole that electrically connects the first electrode and the selection transistor can be configured of polysilicon doped with an impurity, or a high-melting metal or metal silicide such as tungsten, Ti, Pt, Pd, Cu, TiW, TiNW, WSi₂, MoSi₂, and the like, and can be formed on the basis of a CVD method or a PVD method exemplified by a sputtering method. Further, a material constituting the insulating layer and the interlayer insulating layer can be exemplified by silicon oxide (SiO₂), silicon nitride (SiN), SiON, SiOC, SiOF, SiCN, SOG (spin-on glass), NSG (non-doped silicate glass), BPSG (boron phosphorus silicate glass), PSG, BSG, PbSG, AsSG, SbSG, LTO, and Al₂O₃.

Alternatively, low dielectric constant insulating materials (for example, fluorocarbons, cycloperfluorocarbon polymers, benzocyclobutene, cyclic fluororesins, polytetrafluoroethylene, amorphous tetrafluoroethylene, polyaryl ethers, fluorinated aryl ethers, fluorinated polyimides, organic SOG, parylene, fluorinated fullerenes, amorphous carbon), polyimide resins, fluororesins, Silk (a trademark of The Dow Chemical Co., a coating type low dielectric constant interlayer insulating film material), Flare (a trademark of Honeywell Electronic Materials Co., polyallyl ether (PAE) based material) can be mentioned, and these can be used singly or in an appropriate combination. Alternatively, polymethyl methacrylate (PMMA); polyvinyl phenol (PVP); polyvinyl alcohol (PVA); polyimides; polycarbonates (PC); polyethylene terephthalate (PET); polystyrene; silanol derivatives (silane coupling agents) such as N-2-(aminoethyl)-3-aminopropyltrimethoxysilane AEAPTMS), 3-mercaptopropyltrimethoxysilane (MPTMS), and octadecyltrichlorosilane (OTS); novolac-type phenolic resins; fluororesins; organic insulating materials (organic polymers) exemplified by linear hydrocarbons having a functional group capable of binding to a control electrode at one end, such as octadecanethiol and dodecylisosianate, can be mentioned, and combinations thereof can also be used. The insulating layer and the interlayer insulating layer can be formed based on known methods such as various CVD methods, coating methods, various PVD methods including a sputtering method and a vacuum vapor deposition method, various printing methods such as a screen printing method, and a sol-gel method.

As electronic devices incorporating the magnetoresistive element of the present disclosure, portable electronic devices such as mobile devices, game devices, music devices, and video devices, and stationary electronic devices can be mentioned, and magnetic heads can also be mentioned. Further, a storage device configured of a nonvolatile storage element array in which the magnetoresistive elements (specifically, storage elements, more specifically, nonvolatile memory cells) of the present disclosure are arranged in a two-dimensional matrix can also be mentioned.

### Embodiment 1

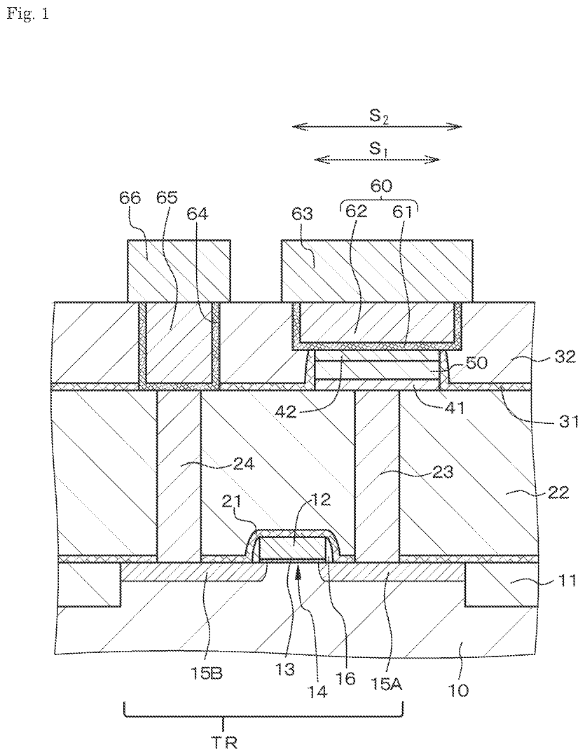

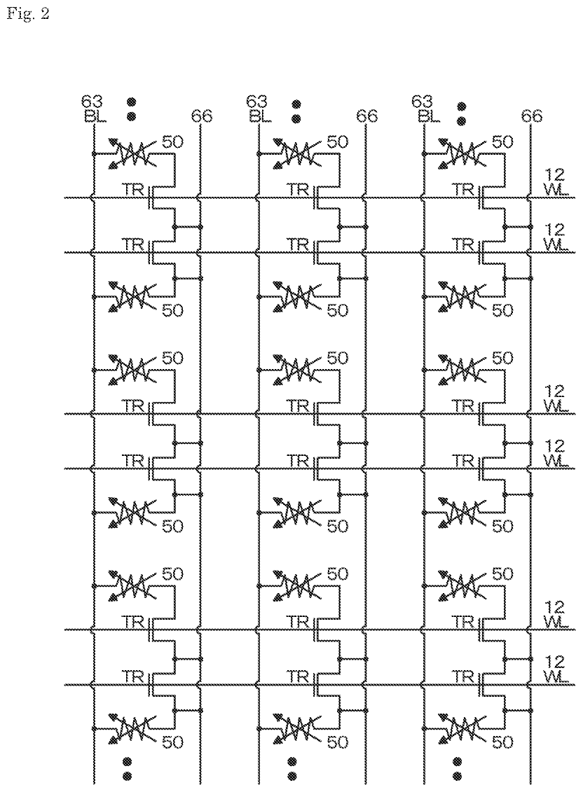

Embodiment 1 relates to the magnetoresistive element of the present disclosure, more specifically, for example, a magnetoresistive element constituting a storage element (nonvolatile memory cell). FIG. 1 shows a schematic partial cross-sectional view of the magnetoresistive element (spin-injection type magnetoresistive element) of Embodiment 1 including a selection transistor, and FIG. 2 shows an equivalent circuit diagram. The nonvolatile memory cell is formed by arranging the magnetoresistive elements of Embodiment 1 in a two-dimensional matrix. The magnetoresistive elements constitute a nonvolatile memory cell.

The magnetoresistive element of Embodiment 1 or Embodiments 2 to 4 described hereinbelow has at least a layered structure 50 composed of a magnetization fixed layer, an intermediate layer and a storage layer, wherein a metal layer 61 is formed on or above the layered structure 50 (specifically, above the layered structure 50 in Embodiment 1 or Embodiments 2 to 4 described hereinbelow), and an orthogonal projection image of the layered structure 50 with respect to the metal layer 61 is contained in the metal layer 61.

Assuming that an oxide formation Gibbs energy of a metal atom constituting the metal layer 61 at a temperature T (° C.) of 0° C. or higher and 400° C. or lower is E_{Gib-0}(T), and a minimum Gibbs energy among oxide formation Gibbs energies of metal atoms constituting the magnetization fixed layer and the storage layer at the temperature T is E_{Gib-1} (T), the following formula (1) is satisfied. Alternatively, assuming that an oxide formation Gibbs energy of a metal atom constituting the metal layer 61 at a temperature T (° C.) of 0° C. or higher and 400° C. or lower is E_{Gib-0}(T), and a maximum Gibbs energy among oxide formation Gibbs energies of metal atoms constituting the intermediate layer at the temperature T is E_{Gib-2}(T), the following formula (2) is satisfied. Depending on the configuration of the magnetoresistive element, either one of the formulas (1) and (2) may be satisfied, but in the magnetoresistive element of Embodiment 1 or Embodiments 2 to 4 described hereinbelow, at the temperature T, the formulas (1) and (2) are satisfied at the same time.

E_{Gib-0}(T)≤E_{Gib-1}(T) (1)

E_{Gib-2}(T)≤E_{Gib-0}(T) (2)

Here, in the magnetoresistive element of Embodiment 1 or Embodiments 2 to 4 described hereinbelow, the metal layer 61 includes at least one kind of metal atom selected from the group consisting of a titanium (Ti) atom, an aluminum (Al) atom, and a magnesium (Mg) atom. Specifically, the metal layer 61 is composed of titanium (Ti). Titanium (Ti) also has a hydrogen storage effect. More specifically, the metal layer 61 is illustrated as one layer, but in reality, the metal layer 61 has a Ti/TiN layered structure. Ti may be an upper layer or a lower layer. However, it goes without saying that the metal layer 61 can be composed of a Ti layer as a single layer. In addition, the metal atom constituting the metal layer 61 is contained in the metal layer 61 at 60 atomic % or more, preferably 80 atomic % or more, but in the magnetoresistive element of Embodiment 1 or Embodiments 2 to 4 described hereinbelow, specifically, the metal atoms constituting the metal layer 61 constitute the entire metal layer 61. It is desirable than the thickness of the metal layer 61 be 1×10⁻⁸ m or more, preferably 2×10⁻⁸ m or more, and specifically, the thickness of the facing surface of the metal layer 61 facing the layered structure 50 was 20 nm.

Further, in the magnetoresistive element of Embodiment 1 or Embodiments 2 to 4 described hereinbelow, the metal atom constituting the magnetization fixed layer and the storage layer includes a cobalt (Co) atom, an iron (Fe) atom, or a cobalt atom and an iron atom (Co—Fe). Specifically, the magnetization fixed layer and the storage layer are composed of a Co—Fe—B alloy layer [for example, (Co₂₀Fe₈₀)₈₀B₂₀ alloy layer]. Further, the metal atom constituting the intermediate layer composed of a non-magnetic material that functions as a tunnel insulating film includes a magnesium (Mg) atom or an aluminum (Al) atom. Specifically, the intermediate layer is composed of MgO. By configuring the intermediate layer of the MgO layer, the magnetic reluctance change rate (MR ratio) can be increased, which can improve the efficiency of spin injection and can reduce the magnetization reversal current density required for reversing the magnetization direction of the storage layer. The oxide formation Gibbs energy (T=400° C.) of Ti, Co, Fe, Mg, and Si is shown in Table 1 below.

TABLE 1
Oxide formation Gibbs energy (value at 673° K.)

| | | |
|---|---|---|
| Ti | −800 | kJ/mol-O₂ |
| Al | −990 | kJ/mol-O₂ |
| Mg | −1120 | kJ/mol-O₂ |
| Co | −380 | kJ/mol-O₂ |
| Fe | −433 | kJ/mol-O₂ |
| Si | −763 | kJ/mol-O₂ |

In the magnetoresistive element of Embodiment 1, the layered structure 50 is surrounded by insulating layers 31 and 32; a connection portion 60 connected to the layered structure 50 is formed on or above the layered structure 50 (specifically, above the layered structure 50); and the metal layer 61 is formed on the inner wall of the connection portion 60.

Specifically, the connection portion 60 is configured of the metal layer 61 and a contact hole portion 62 composed of tungsten (W). Assuming that the area of the facing surface of the layered structure 50 facing the metal layer 61 is Si and the area of the facing surface of the metal layer 61 facing the layered structure 50 is S₂, it is preferable that

S₂/S₁≥1

desirably

S₂/S₁≥2

be satisfied. Specifically, for example, S₂/S₁=2. The three-dimensional shape of the layered structure 50 is cylindrical (columnar), but is not limited to this, and may be, for example, a quadrangular prism. By design, the planar shapes of the facing surface of the layered structure 50 facing the metal layer 61 and the facing surface of the metal layer 61 facing the layered structure 50 are concentric circles.

In the magnetoresistive element of Embodiment 1 or Embodiments 2 to 4 described hereinbelow, the magnetization direction of the storage layer changes according to the information to be stored. In the storage layer, the easy axis of magnetization is parallel to the layering direction of the layered structure 50 (that is, a perpendicular magnetization type is realized). That is, the magnetoresistive element is composed of a spin injection type magnetoresistance effect element of a perpendicular magnetization system. In other words, the magnetoresistive element is configured of a MTJ element. The magnetization direction of the magnetization fixed layer is the magnetization direction that is the reference for the information to be stored in the storage layer, and information “0” and information “1” are specified by the relative angles of the magnetization direction of the storage layer and the magnetization direction of the magnetization fixed layer. The first surface of the layered structure 50 is in contact with the first electrode 41, the second surface of the layered structure 50 is in contact with the second electrode 42, and a current is passed between the first electrode 41 and the second electrode 42 thereby storing information in the storage layer (magnetization reversal current). The magnetization fixed layer may constitute the first surface of the layered structure 50, or the storage layer may constitute the first surface of the layered structure 50.

The various layer configurations described above are listed in Table 2 below.

```
TABLE 2
Layered structure
  Storage layer: (Co₂₀Fe₈₀)₈₀B₂₀ layer with a film thickness of 1.6 nm
  Intermediate layer: MgO layer with a film thickness of 1.0 nm
  Magnetization fixing layer: (Co₂₀Fe₈₀)₈₀B₂₀ layer with a film thickness
  of 1.0 nm
First electrode: TaN with a thickness of 10 nm
Second electrode: Ta with a thickness of 30 nm
Metal layer: Ti layer with a film thickness of 20 nm
```

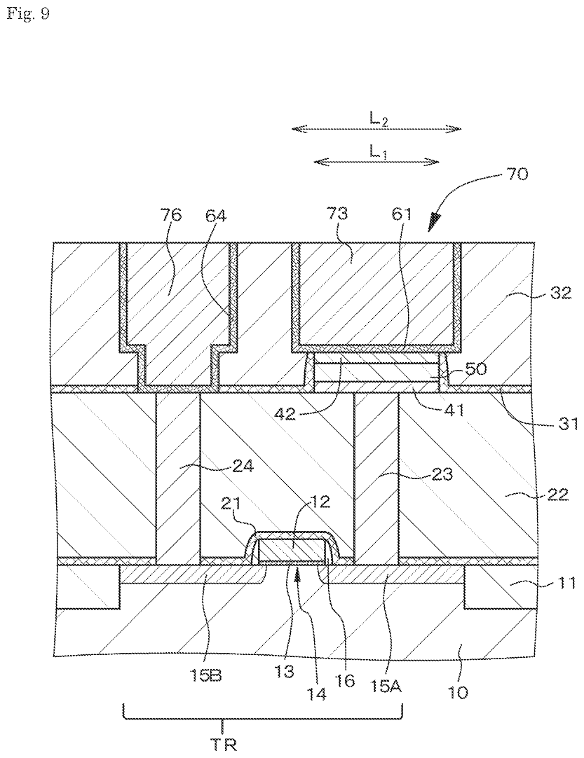

In the magnetoresistive element of Embodiment 1 or Embodiments 2 to 4 described hereinbelow, a selection transistor TR composed of a field effect transistor is provided below the layered structure 50, and for example, a form is possible in which a projection image in the extension direction of a second wiring (bit wire) 63 connected to the second electrode 42 is orthogonal to a projection image in the extension direction of a gate electrode (for example, which also functions as a word line or an address line) 12 constituting the field effect transistor TR, and a form is also possible in which the projection image in the extension direction of the second wiring 63 is parallel to the projection image in the extension direction of the gate electrode 12 constituting the field effect transistor TR. In a more specific configuration, the projection image in the extension direction of the second wiring 63 is orthogonal to the projection image in the extension direction of the gate electrode 12 and parallel to the projection image in the extension direction of a first wiring (sense wire) 66. However, in FIG. 1 or FIGS. 9, 10, 11, 12, 13, 14, 15, 16, 17, and 20 described hereinbelow, the extension directions of the gate electrode 12, second wiring 63, 73, and 83, and first wiring 66, 76, and 86 are different from those in the description hereinabove for simplification of the figures. The second wiring 63, 73, and 83 and the first wiring 66, 76, and 86 extend in the direction perpendicular to the plane of the figures.

For example, the selection transistor TR formed on a semiconductor substrate 10 composed of a silicon semiconductor substrate is configured of a channel forming region 14 and source/drain regions 15A and 15B formed on the semiconductor substrate 10, and the gate electrode 12 provided opposite the channel forming region 14 with a gate insulating layer 13 interposed therebetween. A gate sidewall 16 composed of SiO₂ is formed on the side wall of the gate electrode 12. The selection transistor TR is covered with interlayer insulating layers 21 and 22. The interlayer insulating layer 21 is composed of SiN, and the interlayer insulating layer 22 is composed of SiO₂. Reference numeral 11 denotes an element separation region.

The first electrode 41 is formed on the interlayer insulating layer 22;

the first electrode 41 is electrically connected to one source/drain region 15A of the selection transistor TR through the connection hole 23 provided in the interlayer insulating layers 22 and 21;
the layered structure 50 is in contact with the first electrode 41 and the second electrode 42; and
insulating layers 31 and 32 cover the interlayer insulating layer 22 and surround the first electrode 41, the layered structure 50, and the second electrode 42. The insulating layer 31 is composed of SiN, and the insulating layer 32 is composed of SiO₂.

The other source/drain region 15B of the selection transistor TR is connected to the first wiring (sense wire) 66 via a connection hole 24 provided in the interlayer insulating layers 22 and 21 and a connection hole 65 formed in the insulating layers 31 and 32.

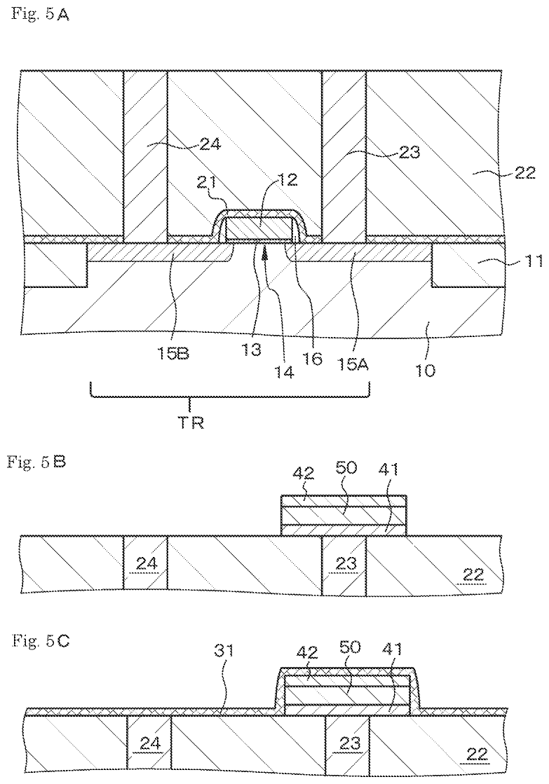

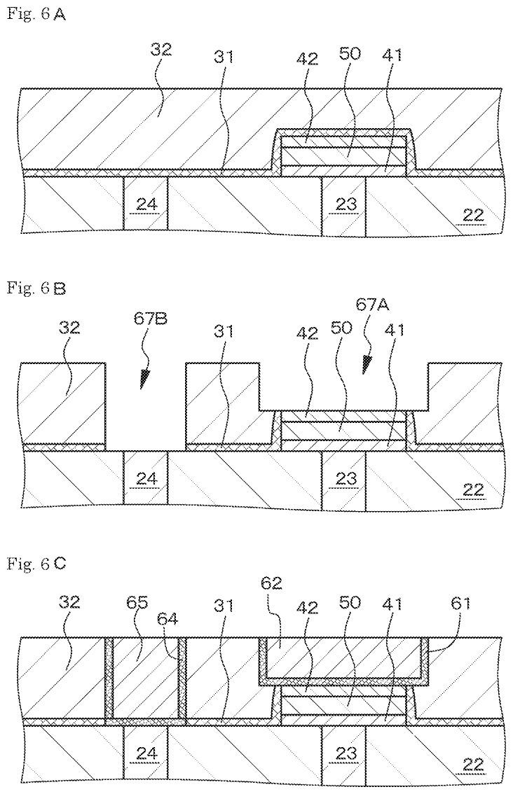

Hereinafter, the outline of the method for manufacturing the magnetoresistive element of Embodiment 1 will be described with reference to FIGS. 5A, 5B, 5C, 6A, 6B, and 6C. In FIGS. 5B, 5C, 6A, 6B, 6C, 7A, 7B, 8A and 8B, the selection transistor TR is not shown.

[Step-100]

First, based on a well-known method, the element separation region 11 is formed on the semiconductor substrate 10 composed of a silicon semiconductor substrate, and the selection transistor TR composed of the gate insulating layer 13, the gate electrode 12, the gate sidewall 16, and the source/drain regions 15A and 15B is formed on a portion of the semiconductor substrate 10 surrounded by the element separation region 11. The portion of the semiconductor substrate 10 located between the source/drain region 15A and the source/drain region 15B corresponds to a channel forming region 14. Next, the interlayer insulating layers 21 and 22 are formed. Then, the connection hole 23 composed of a tungsten plug is formed in the portions of the interlayer insulating layers 21 and 22 above one source/drain region 15A, and the connection hole 24 composed of a tungsten plug is formed in the portions of the interlayer insulating layers 21 and 22 above the other source/drain region 15B. In this way, the selection transistor TR covered with the interlayer insulating layers 22 and 21 can be obtained (see FIG. 5A).

[Step-110]

After that, the first electrode 41, the layered structure 50 and the second electrode 42 are formed on the interlayer insulating layer 22, and then the second electrode 42, the layered structure 50 and the first electrode 41 are etched based on a reactive ion etching method (RIE method) (see FIG. 5B). The first electrode 41 is in contact with the connection hole 23. The intermediate layer composed of magnesium oxide (MgO) was formed by forming an MgO layer on the basis of a RF magnetron sputtering method. The other layers were formed on the basis of a DC magnetron sputtering method. Instead of patterning each layer by the RIE method, each layer can be patterned based on an ion milling method (ion beam etching method).

[Step-120]

Next, the insulating layers 31 and 32 are formed on the entire surface (see FIGS. 5C and 6A). Then, an opening 67A is formed in the insulating layers 31 and 32 above the layered structure 50. The layered structure 50 is exposed at the bottom of the opening 67A. Further, an opening 67B is formed in the insulating layers 31 and 32 above the connection hole 24. The connection hole 24 is exposed at the bottom of the opening 67B. In this way, the structure shown in FIG. 6B can be obtained.

[Step-130]

After that, metal layers 61 and 64 are formed on the entire surface on the basis of a sputtering method, a tungsten layer is formed on the entire surface on the basis of a CVD method, and the tungsten layer and the metal layers 61 and 64 on the insulating layer 32 are removed by a CMP method. In this way, the structure shown in FIG. 6C can be obtained.

[Step-140]

Next, the second wiring (bit wire) 63 and the first wiring (sense wire) 66 are formed on the insulating layer 32 on the basis of a well-known method. The second wiring 63 is in contact with the connection portion 60 composed of the metal layer 61 and the contact hole portion 62. Further, the first wiring 66 is in contact with the metal layer 64 and the connection hole 65. In this way, the magnetoresistive element of Embodiment 1 shown in FIG. 1 can be obtained.

As described above, a general MOS manufacturing process can be adopted for the manufacture of the magnetoresistive element of Embodiment 1, and the element can be adopted as a general-purpose memory.

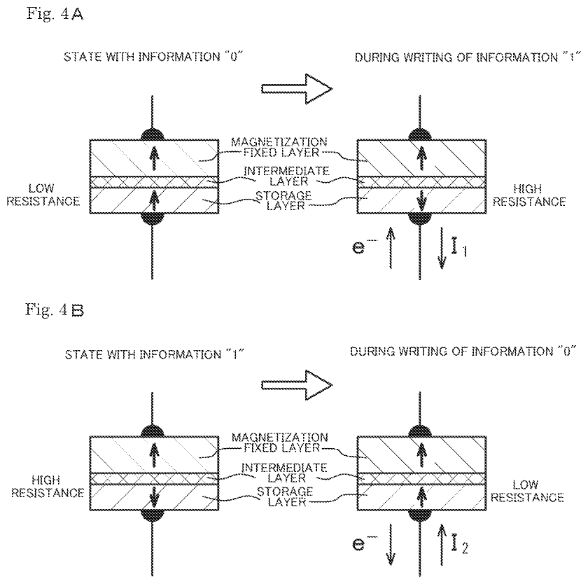

As shown in the conceptual diagrams in FIGS. 3A and 4A, it is assumed that information “0” stored in the storage layer is rewritten to “1”. That is, in the parallel magnetization state, a write current (magnetization reversal current) I₁ is passed from the magnetization fixed layer to the selection transistor TR via the storage layer. In other words, electrons flow from the storage layer toward the magnetization fixed layer. Specifically, for example, V_{dd} is applied to the second wiring (bit wire) 63, and the other source/drain region 15B of the selection transistor TR is grounded. Electrons with spins in one direction that have reached the magnetization fixed layer pass through the magnetization fixed layer. Meanwhile, electrons with spins in the other direction are reflected by the magnetization fixed layer. Where these electrons enter the storage layer, torque is applied to the storage layer, and the storage layer is reversed to the antiparallel magnetization state. Here, since the magnetization direction of the magnetization fixed layer is fixed, the reversal thereof is impossible, and it may be considered that the storage layer is reversed in order to preserve the angular momentum of the entire system.

As shown in the conceptual diagrams in FIGS. 3B and 4B, it is assumed that information “1” stored in the storage layer is rewritten to “0”. That is, in the antiparallel magnetization state, a write current I₂ is passed from the selection transistor TR to the magnetization fixed layer via the storage layer. In other words, electrons flow from the magnetization fixed layer toward the storage layer. Specifically, for example, V_{dd} is applied to the other source/drain region 15B of the selection transistor TR, and the second wiring (bit wire) 63 is grounded. For electrons that have passed through the magnetization fixed layer, there is a difference in spin polarization, that is, the number of upwards and downwards. Where the thickness of the intermediate layer is sufficiently small and the storage layer is reached before the spin polarization is relaxed and a non-polarized state of a normal non-magnetic material is assumed (the same number of upward and downward states), the sign of the spin polarization degree is reversed, so that for some electrons, reversal occurs, that is, the orientation of spin angular momentum is changed in order to reduce the energy of the whole system. At this time, since the total angular momentum of the system needs to be conserved, a counter-action equivalent to the total change of the angular momentum due to the electrons with changed orientation is given to the magnetic momentum in the storage layer. Where the current, that is, the number of electrons passing through the magnetization fixed layer per unit time is small, the total number of electrons that change the orientation is also small, so the change in angular momentum generated in the magnetic momentum in the storage layer is also small. Where the current increases, a large number of changes in angular momentum can be given to the storage layer within a unit time. The temporal change of angular momentum is torque, and where the torque exceeds a certain threshold, the magnetic momentum of the storage layer starts to reverse and becomes stable at a 180-degree rotation due to uniaxial anisotropy thereof. That is, the reversal from the antiparallel magnetization state to the parallel magnetization state occurs, and the information “0” is stored in the storage layer.

When the information written in the storage layer is read out, the selection transistor TR in the magnetoresistive element from which the information should be read out is brought into a conductive state. Then, a current is passed between the second wiring (bit wire) 63 and the first wiring (sense wire) 66, and a potential appearing in the second wiring 63 is inputted to the other input section of a comparator circuit (not shown) constituting a comparison circuit (not shown). Meanwhile, a potential from a circuit (not shown) for obtaining a reference resistance value is inputted to one input section of the comparator circuit constituting the comparison circuit. In the comparison circuit, whether the potential appearing in the second wiring 63 is high or low is compared with reference to the potential from the circuit for obtaining the reference resistance value, and the comparison result (information 0/1) is outputted from an output section of the comparator circuit constituting the comparison circuit.

Since the formula (1) [E_{Gib-0}<E_{Gib-1}] is satisfied in the magnetoresistive element of Embodiment 1, the metal layer is more likely to be oxidized than the magnetization fixed layer and the storage layer in the oxidizing atmosphere in the manufacturing process of the magnetoresistive element. Further, since the formula (2) [E_{Gib-2}≤E_{Gib-0}] is satisfied, the metal layer is more likely to be reduced than the intermediate layer in the reducing atmosphere in the manufacturing process of the magnetoresistive element. As a result of the above, it is possible to obtain a magnetoresistive element which has high stability with respect to heat and the atmosphere and in which the magnetization fixed layer and the storage layer are less likely to be oxidized in the oxidizing atmosphere, and the intermediate layer is less likely to be reduced in the reducing atmosphere.

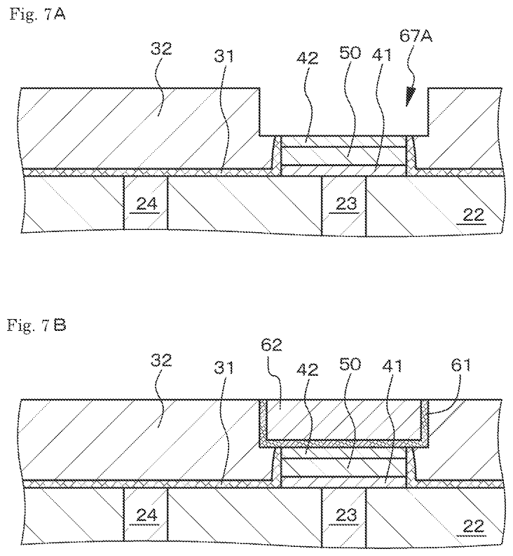

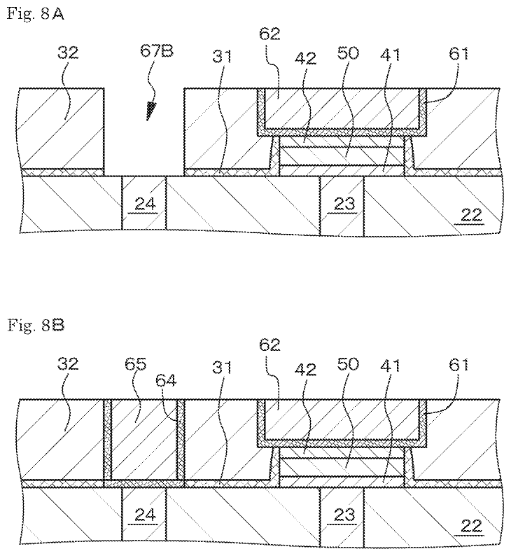

For example, when the height of the layered structure 50 is large, the depth of the opening 67A and the depth of the opening 67B are significantly different, and it may be difficult to form the contact hole portion 62 and the connection hole 65 at the same time. In such a case, as shown in FIGS. 7A, 7B, 8A, and 8B, it is possible to form the opening 67A, then form the metal layer 61 and the contact hole portion 62, next form the opening 67B, and then form the metal layer 64 and the connection hole 65. The order of forming the contact hole portion 62 and the like and the connection hole 65 and the like may be reversed. That is, it is possible to form the opening 67B, then form the metal layer 64 and the connection hole 65, next form the opening 67A, and then form the metal layer 61 and the contact hole portion 62.

### Embodiment 2

Embodiment 2 is a modification of Embodiment 1. FIG. 9 shows a schematic partial cross-sectional view of the magnetoresistive element of Embodiment 2.

In the magnetoresistive element of Embodiment 2, the connection portion 70 is configured of the metal layer 61 and a part of the wiring (second wiring and also a bit wire) 73 having a damascene structure. Further, assuming that the length of the portion of the layered structure 50 facing the metal layer 61 in a virtual plane (virtual plane parallel to the plane in the figure) orthogonal to the extension direction of the wiring 73 (direction perpendicular to the plane in the figure) is L₁, and the length of the portion of the metal layer 61 facing the layered structure 50 in the virtual plane is L₂,

L₂/L₁≥1

desirably

L₂/L₁≥2

is satisfied. Specifically, L₂/L₁=3.

The damascene structure itself is a well-known structure.

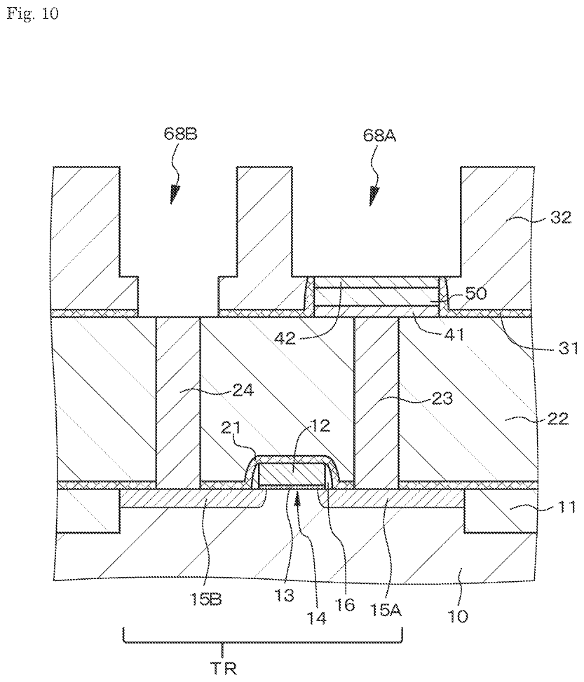

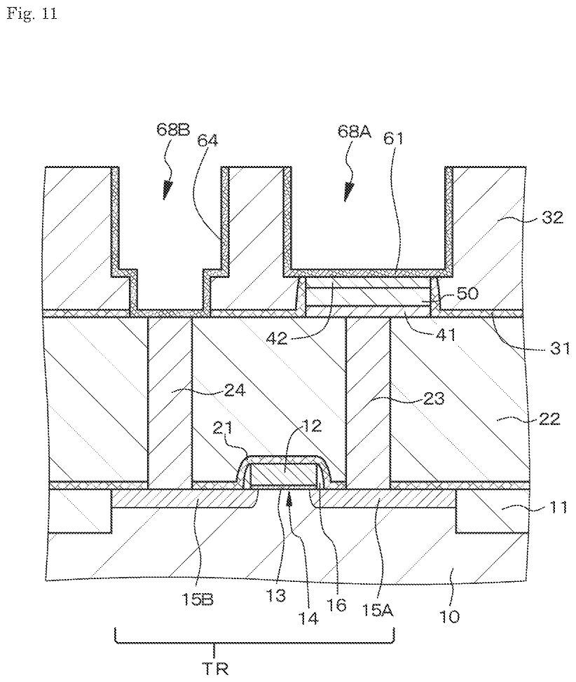

In the manufacture of the magnetoresistive element of Embodiment 2, in a step similar to [Step-120] of Embodiment 1, the insulating layers 31 and 32 are formed on the entire surface, and then a groove 68A is formed in the insulating layers 31 and 32 above the layered structure 50. The layered structure 50 is exposed at the bottom of the groove 68A. Further, a groove 68B is formed in the insulating layers 31 and 32 above the connection hole 24. The connection hole 24 is exposed at the bottom of the groove 68B. In this way, the structure shown in FIG. 10 can be obtained. Next, in a step similar to [Step-130] of Embodiment 1, the metal layers 61 and 64 composed of titanium are formed on the entire surface on the basis of a sputtering method (see FIG. 11), and further, a copper layer is formed on the entire surface on the basis of a CVD method, and the copper layer and the metal layers 61 and 64 on the insulating layer 32 are removed by a CMP method. In this way, it is possible to obtain the magnetoresistive element of Embodiment 2 shown in FIG. 9, which has the second wiring (bit wire) 73 and the first wiring (sense wire) 76 having a damascene structure. The second wiring (bit wire) 73 and the first wiring (sense wire) 76 extend in the direction perpendicular to the plane in the figure.

Except for the above points, the configuration and structure of the magnetoresistive element of Embodiment 2 can be the same as the configuration and structure of the magnetoresistive element of Embodiment 1, and therefore detailed description thereof will be omitted.

### Embodiment 3

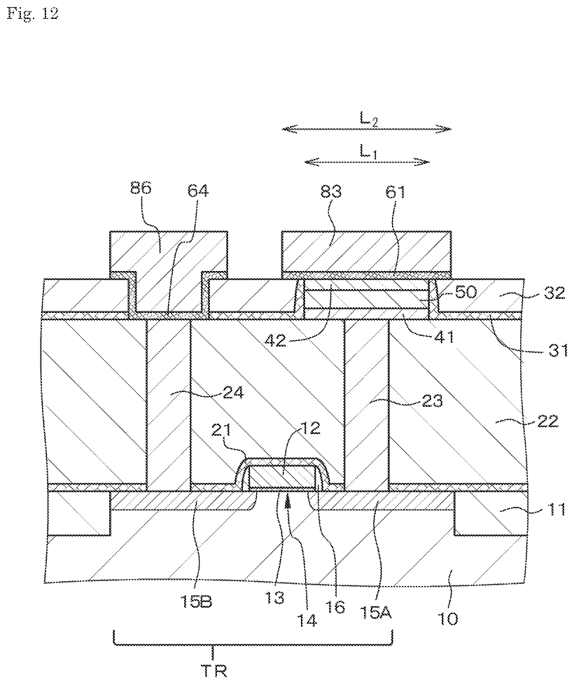

Embodiment 3 is also a modification of Embodiment 1. A schematic partial cross-sectional view of the magnetoresistive element of Embodiment 3 is shown in FIG. 12.

In the magnetoresistive element of Embodiment 3,

the layered structure 50 is surrounded by the insulating layers 31 and 32; the metal layer 61 is formed on or above the layered structure 50 (specifically formed above the layered structure 50) and is connected to the layered structure 50; and
the wiring layer 83 is formed on the metal layer 61. Further, assuming that the length of the portion of the layered structure 50 facing the metal layer 61 in a virtual plane (virtual plane parallel to the plane in the figure) orthogonal to the extension direction of the wiring layer 83 (direction perpendicular to the plane in the figure) is L₁, and the length of the portion of the metal layer 61 facing the layered structure 50 in the virtual plane is L₂,

L₂/L₁≥1

desirably

L₂/L₁≥2

is satisfied. Specifically, L₂/L₁=5.

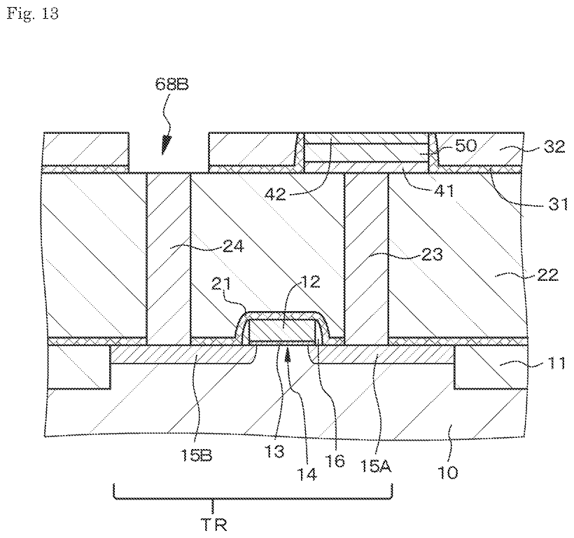

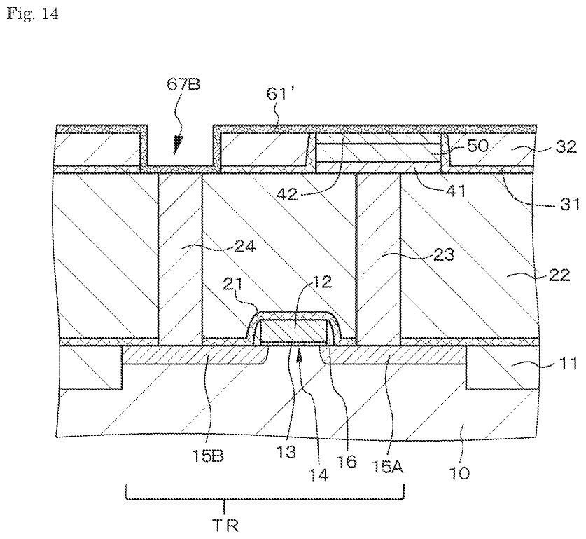

In the manufacture of the magnetoresistive element of Embodiment 3, in a step similar to [Step-120] of Embodiment 1, the insulating layers 31 and 32 are formed on the entire surface, the insulating layers 31 and 32 are then planarized, the top surface of the second electrode 42 is exposed, and the opening 67B is thereafter formed in the insulating layers 31 and 32 above the connection hole 24. The connection hole 24 is exposed at the bottom of the opening 67B. In this way, the structure shown in FIG. 13 can be obtained. Next, in a step similar to [Step-130] of Embodiment 1, a metal layer 61′ composed of titanium is formed on the entire surface on the basis of a sputtering method (see FIG. 14), and further, an aluminum layer is formed on the entire surface on the basis of a sputtering method, and the aluminum layer and the metal layer 61′ on the insulating layer 32 are patterned and removed based on an etching method. In this way, the magnetoresistive element of Embodiment 3 shown in FIG. 12 that has the second wiring (bit wire) 83 and the first wiring (sense wire) 86 can be obtained. The second wiring (bit wire) 83 and the first wiring (sense wire) 86 extend in the direction perpendicular to the plane in the figure.

Except for the above points, the configuration and structure of the magnetoresistive element of Embodiment 3 can be the same as the configuration and structure of the magnetoresistive element of Embodiment 1, and therefore detailed description thereof will be omitted.

In some cases, a connection hole composed of, for example, a tungsten plug may be formed between the metal layer 61 and the second electrode 42. Even if the metal layer 61 is not positioned adjacent to the layered structure 50, the metal layer 61 can exert the effects of suppressing oxidation of the magnetization fixed layer and the storage layer and suppressing reduction of the intermediate layer. Further, the width of the metal layer 61 and the wiring layer 83 located above the layered structure 50 may be larger than the width of other portions. Alternatively, the width of the metal layer 61 may be larger than the width of the wiring layer 83. That is, the metal layer 61 may be formed in a large area as long as short circuiting with the adjacent second wiring (bit wire) 83 and the first wiring (sense wire) 86 is avoided.

### Embodiment 4

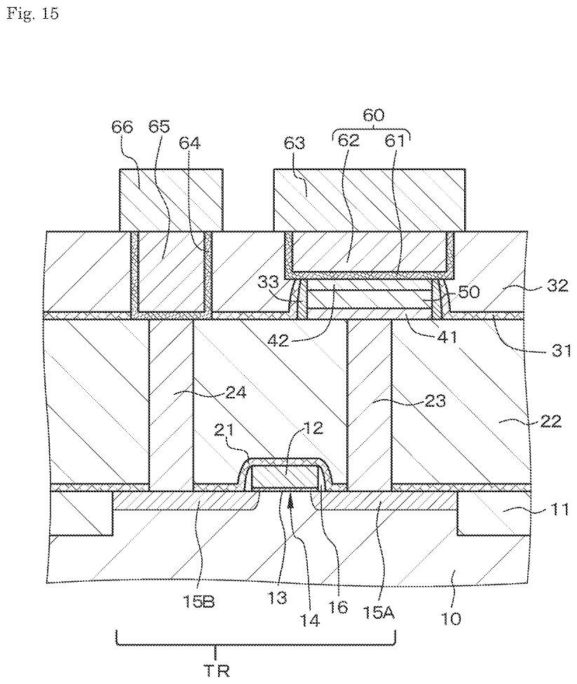

Embodiment 4 is a modification of Embodiments 1 to 3. A schematic partial cross-sectional view of the magnetoresistive element of Embodiment 4 is shown in FIG. 15.

In the magnetoresistive element of Embodiment 4, the side surface of the layered structure 50 is covered with the sidewall 33. In this case, assuming that the oxide formation Gibbs energy of the atom constituting the sidewall 33 at the temperature T is E_{Gib-SW}(T),

E_{Gib-2}(T)≤E_{Gib-SW}(T)<E_{Gib-1}(T) (3)

is satisfied. Furthermore, the atom constituting the sidewall 33 includes at least one atom selected from the group consisting of titanium (Ti), aluminum (Al), magnesium (Mg) and silicon (Si). Specifically, the atom constituting the sidewall 33 was silicon (Si). The sidewall 33 is composed of SiO₂.

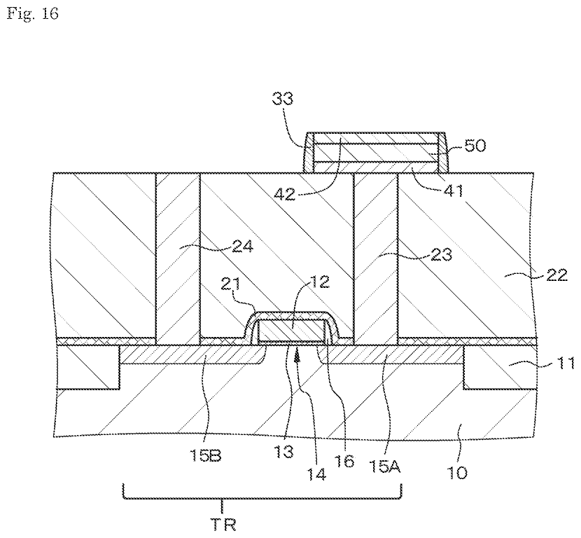

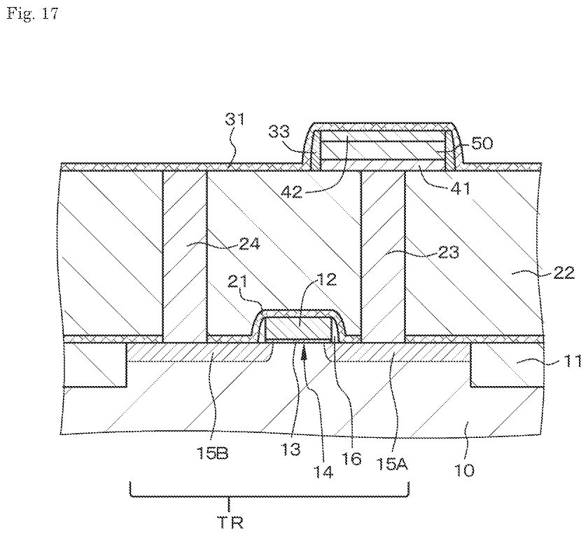

In the manufacture of the magnetoresistive element of Embodiment 4, the sidewall 33 composed of SiO₂ can be formed on the side surface of the layered structure 50 by, for example, forming a SiO₂ layer on the entire surface and then etching back the SiO₂ layer between [Step-110] and [Step-120] of Embodiment 1 (see FIG. 16 which is a schematic partial end view of the layered structure and the like). A step similar to [Step-120] of Embodiment 1 may be subsequently executed (see FIG. 17).

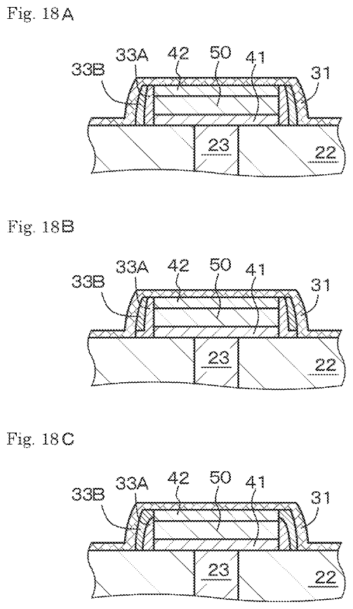

Schematic partial cross-sectional views of a layered structure and the like of a modification example of the magnetoresistive element of Embodiment 4 is shown in FIGS. 18A, 18B and 18C.

In the structure shown in FIG. 18A, the sidewall is configured of a first sidewall 33A composed of SiN and a second sidewall 33B composed of SiO₂. The first sidewall 33A is in contact with the side surface of the layered structure 50, and the second sidewall 33B is in contact with the insulating layer 31 composed of SiN.

In the structure shown in FIG. 18B, similarly to the structure shown in FIG. 18A, the sidewall is composed of the first sidewall 33A composed of SiN and the second sidewall 33B composed of SiO₂. However, the bottom of the first sidewall 33A extends over the interlayer insulating layer 22.

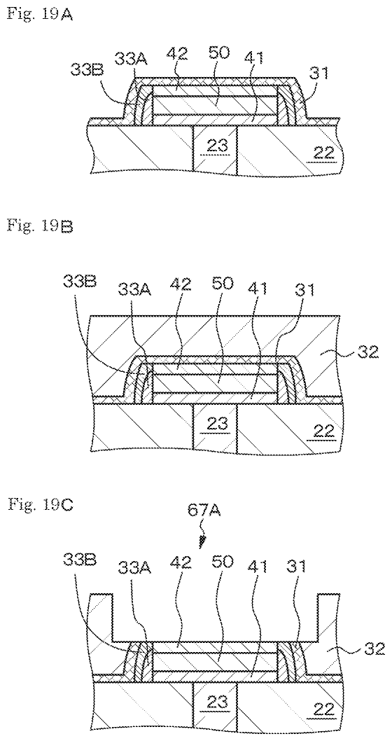

In the structure shown in FIG. 18C, similarly to the structure shown in FIG. 18A, the sidewall is composed of the first sidewall 33A composed of SiN and the second sidewall 33B composed of SiO₂. However, the upper part of the first sidewall 33A is covered by the second sidewall 33B. Similarly to the structure shown in FIG. 18B, the bottom of the first sidewall 33A may extend over the interlayer insulating layer 22. When such a sidewall structure is formed, the insulating layer 31 composed of SiN is formed on the entire surface as shown in FIG. 19A, and then the insulating layer 32 composed of SiO₂ is formed on the entire surface as shown in FIG. 19B. Then, for example, in order to form a connection portion, the opening 67A is formed in the insulating layer 32 and the insulating layer 31 as shown in FIG. 19C. Here, when the insulating layer 31 composed of SiN is etched, the upper portion of the first sidewall 33A composed of SiN is covered with the second sidewall 33B composed of SiO₂, so that the first sidewall 33A is not etched.

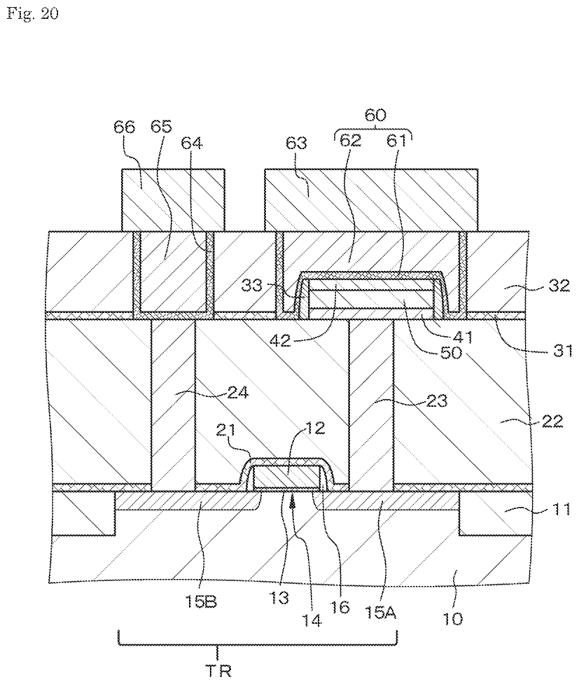

A schematic partial cross-sectional view of another modification example of the magnetoresistive element of Embodiment 4 is shown in FIG. 20. In the modification example of Embodiment 4, for example, at least a part of the sidewall 33 composed of SiO₂ or SiN (in the illustrated example, the entire sidewall 33) is covered with the metal layer 61. With such a structure, structural changes (for example, the wiring structure) in a logic region can be minimized, so that the influence on the characteristics of the logic circuit such as the increase in the resistance value and the capacitance value can be reduced and combined mounting of magnetoresistive elements is facilitated.

Except for the above points, the configuration and structure of the magnetoresistive element of Embodiment 4 can be the same as the configuration and structure of the magnetoresistive element of Embodiments 1 to 3, and detailed description thereof will be omitted.

### Embodiment 5

Embodiment 5 relates to an electronic device equipped with the magnetoresistive element described Embodiments 1 to 4, specifically, a magnetic head. The magnetic head can be applied to various electronic devices, electrical devices, and the like, for example, such as hard disk drives, integrated circuit chips, personal computers, mobile terminals, mobile phones, and magnetic sensor devices.

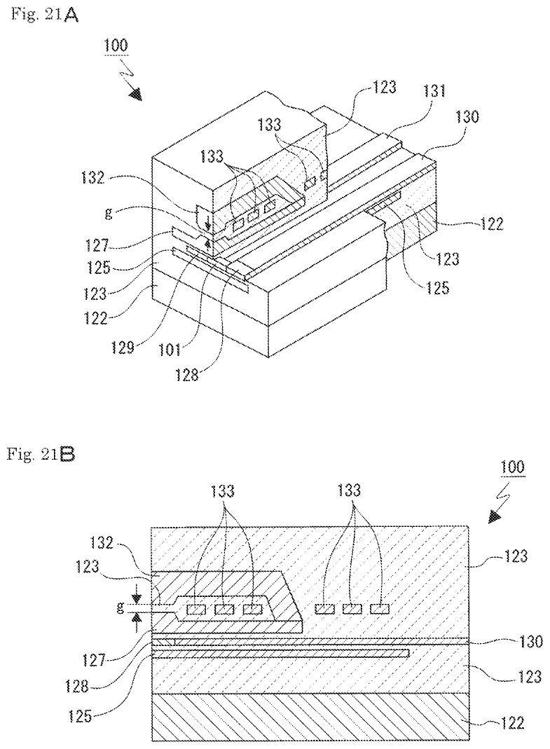

As an example, FIGS. 21A and 21B show an example in which a magnetoresistive element 101 is used in a composite magnetic head 100. FIG. 21A is a schematic perspective view of the composite magnetic head 100 with a part cut out so that the internal structure thereof could be seen, and FIG. 21B is a schematic cross-sectional view of the composite magnetic head 100.

The composite magnetic head 100 is a magnetic head used for a hard disk device and the like, and in the magnetic head, a magnetoresistance effect type magnetic head provided with the magnetoresistive element described in Embodiments 1 to 4 is formed on a substrate 122, and an inductive magnetic head is further layered and formed on the magnetoresistance effect type magnetic head. Here, the magnetoresistance effect type magnetic head operates as a playback head, and the inductive magnetic head operates as a recording head. That is, in the composite magnetic head 100, the playback head and the recording head are combined.

The magnetoresistance effect type magnetic head installed in the composite magnetic head 100 is a so-called shield type MR head, and includes a first magnetic shield layer 125 formed on the substrate 122 with an insulating layer 123 interposed therebetween, a magnetoresistive element 101 formed on the magnetic shield layer 125 with the insulating layer 123 interposed therebetween, and a second magnetic shield layer 127 formed on the magnetoresistive element 101 with the insulating layer 123 interposed therebetween. The insulating layer 123 is composed of an insulating material such as Al₂O₃ or SiO₂. The first magnetic shield layer 125 is for magnetically shielding the lower layer side of the magnetoresistive element 101, and is composed of a soft magnetic material such as Ni—Fe. The magnetoresistive element 101 is formed on the first magnetic shield layer 125 with the insulating layer 123 interposed therebetween. The magnetoresistive element 101 functions as a magnetosensitive element that detects a magnetic signal from a magnetic recording medium in the magnetoresistance effect type magnetic head. The shape of the magnetoresistive element 101 is substantially rectangular, and one side surface is exposed as a surface facing the magnetic recording medium. Bias layers 128 and 129 are arranged at both ends of the magnetoresistive element 101. Further, connection terminals 130 and 131 connected to the bias layers 128 and 129 are formed. A sense current is supplied to the magnetoresistive element 101 via the connection terminals 130 and 131. The second magnetic shield layer 127 is provided on the upper parts of the bias layers 128 and 129 with the insulating layer 123 interposed therebetween.

The inductive magnetic head layered and formed on the magnetoresistance effect type magnetic head includes a magnetic core configured of the second magnetic shield layer 127 and an upper layer core 132, and a thin film coil 133 formed so as to wind around the magnetic core. The upper layer core 132 forms a closed magnetic path together with the second magnetic shield layer 127, serves as a magnetic core of the inductive magnetic head, and is composed of a soft magnetic material such as Ni—Fe. Here, in the second magnetic shield layer 127 and the upper layer core 132, the front ends thereof are exposed as surfaces facing the magnetic recording medium, and the second magnetic shield layer 127 and the upper layer core 132 are formed so as to be in contact with each other at the rear ends thereof. Here, the front ends of the second magnetic shield layer 127 and the upper layer core 132 are formed such that the second magnetic shield layer 127 and the upper layer core 132 are separated from each other by a predetermined gap g on the surfaces facing of the magnetic recording medium. That is, in the composite magnetic head 100, the second magnetic shield layer 127 not only magnetically shields the upper layer side of the magnetoresistive element 101, but also serves as the magnetic core of the inductive magnetic head, and the magnetic core of the inductive magnetic head is configured of the second magnetic shield layer 127 and the upper layer core 132. The gap g becomes a recording magnetic gap of the inductive magnetic head.

Further, the thin film coil 133 embedded in the insulating layer 123 is formed on the second magnetic shield layer 127. The thin film coil 133 is formed so as to wind around the magnetic core configured of the second magnetic shield layer 127 and the upper layer core 132. Although not shown, both ends of the thin film coil 133 are exposed to the outside, and terminals formed at both ends of the thin film coil 133 serve as external connection terminals for the inductive magnetic head. That is, when recording a magnetic signal on a magnetic recording medium, a recording current is supplied to the thin film coil 133 from these external connection terminals.

The composite magnetic head 100 as described above is equipped with the magnetoresistance effect type magnetic head as a playback head, and the magnetoresistance effect type magnetic head is provided with the magnetoresistive element 101 described in Embodiments 1 to 4 as a magnetic sensory element that detects a magnetic signal from a magnetic recording medium. Since the magnetoresistive element 101 exhibits extremely excellent characteristics as described above, the magnetoresistance effect type magnetic head can cope with further increase in recording density of magnetic recording.

Although the present disclosure has been described above based on preferred embodiments, the present disclosure is not limited to these embodiments. The various layered structures described in the examples, the materials used, and the like are exemplary and can be changed as appropriate. The magnetization fixed layer may be a layered ferri structure (layered ferri-pin structure) composed of a reference layer and a fixing layer. In some cases, a Si layer may be formed instead of the metal layer. A substrate having a logic region including a nonvolatile storage element array configured of a plurality of magnetoresistive elements of the present disclosure, for example, a substrate including an image pickup element array having a plurality of image pickup elements formed therein can be also attached.

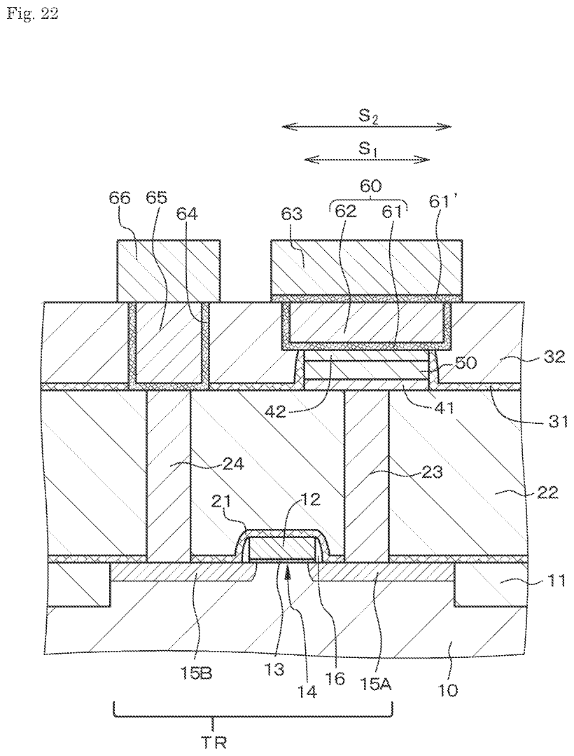

As shown in FIG. 22, in the magnetoresistive element described in Embodiment 1, the Ti layer 61′ that functions as a metal layer may be formed under the second wiring 63. The width of the portion of the second wiring 63 located above the layered structure 50 may be larger than the width of the other portions. That is, it is desirable to form the metal layer 61 in a large area, as long as short circuiting with the adjacent second wiring (bit wire) 63 and the first wiring (sense wire) 66 is avoided.

It is also possible to configure a so-called cross-point type memory cell unit configured of a plurality of magnetoresistive elements (storage element, nonvolatile memory cell). This cross-point type memory cell unit is configured of a plurality of third wirings (word wires) extending in the first direction;

a plurality of second wirings (bit wires) arranged to be vertically separated from third wirings and extending in a second direction different from the extension direction of the third wirings; and
a magnetoresistive element (memory element, nonvolatile memory) arranged in a region where the third wiring and the second wiring overlap and connected to the third wiring and the second wiring.

Information is written or erased in the magnetoresistive element depending on the direction of the voltage applied between the third wiring and the second wiring or the direction of the current flowing between the third wiring and the second wiring. In such a structure, the selection transistor TR is unnecessary.

The present disclosure may also have the following configurations.

[A01]

<Magnetoresistive Element: First Mode>

A magnetoresistive element having at least a layered structure composed of a magnetization fixed layer, an intermediate layer and a storage layer, wherein a metal layer is formed on or above the layered structure;

an orthogonal projection image of the layered structure with respect to the metal layer is contained in the metal layer; and
assuming that an oxide formation Gibbs energy of a metal atom constituting the metal layer at a temperature T (° C.) of 0° C. or higher and 400° C. or lower is E_{Gib-0}(T), and a minimum Gibbs energy among oxide formation Gibbs energies of metal atoms constituting the magnetization fixed layer and the storage layer at the temperature T is E_{Gib-1}(T),

E_{Gib-0}(T)≤E_{Gib-1}(T) (1)

is satisfied.

[A02]

The magnetoresistive element as described in [01], wherein

assuming that a maximum Gibbs energy among oxide formation Gibbs energies of metal atoms constituting the intermediate layer at the temperature T is E_{Gib-2}(T),

E_{Gib-2}(T)≤E_{Gib-0}(T)

is satisfied.

[A03]

<Magnetoresistive Element: Second Mode>

A magnetoresistive element having at least a layered structure composed of a magnetization fixed layer, an intermediate layer and a storage layer, wherein a metal layer is formed on or above the layered structure;

an orthogonal projection image of the layered structure with respect to the metal layer is contained in the metal layer; and
assuming that an oxide formation Gibbs energy of a metal atom constituting the metal layer at a temperature T (° C.) of 0° C. or higher and 400° C. or lower is E_{Gib-0}(T), and a maximum Gibbs energy among oxide formation Gibbs energies of metal atoms constituting the intermediate layer at the temperature T is E_{Gib-2}(T),

E_{Gib-2}(T)≤E_{Gib-0}(T) (2)

is satisfied.

[A04]

The magnetoresistive element as described in any of [A01] to [A03], wherein the metal layer includes at least one metal atom selected from the group consisting of a titanium atom, an aluminum atom, and a magnesium atom.

[A05]

The magnetoresistive element as described in any of [A01] to [A04], wherein a metal atom constituting the magnetization fixed layer and the storage layer includes a cobalt atom, or an iron atom, or a cobalt atom and an iron atom.

[A06]

The magnetoresistive element as described in any of [A01] to [A05], wherein a metal atom constituting the intermediate layer includes a magnesium atom or an aluminum atom.

[A07]

The magnetoresistive element as described in any of [A01] to [A06], wherein a metal atom constituting the metal layer is contained in the metal layer at 60 atomic % or more.

[A08]

The magnetoresistive element as described in any of [A01] to [A07], wherein the thickness of the metal layer is 1×10⁻⁸ m or more.

[A09]

The magnetoresistive element as described in any of [A01] to [A08], wherein a side surface of the layered structure is covered with a sidewall.

[A10]

The magnetoresistive element as described in [A09], wherein assuming that an oxide formation Gibbs energy of a metal atom constituting the sidewall at the temperature T is E_{Gib-SW}(T),

E_{Gib-2}(T)≤E_{Gib-SW}(T)<E_{Gib-1}(T)

is satisfied.

[A11]

The magnetoresistive element as described in [A09] or [A10], wherein an atom constituting the sidewall is at least one kind of atom selected from the group consisting of titanium, aluminum, magnesium, and silicon.

[A12]

The magnetoresistive element as described in any of [A09] to [A11], wherein at least a part of the sidewall is covered with a metal layer.

[A13]

The magnetoresistive element as described in any of [A01] to [A12], wherein the layered structure is surrounded by an insulating layer;

a connection portion connected to the layered structure is formed on or above the layered structure; and
the metal layer is formed on an inner wall of the connection portion.

[A14]

The magnetoresistive element as described in [A13], wherein

the connection portion is configured of a metal layer and a contact hole portion.

[A15]

The magnetoresistive element as described in [A13], wherein

the connection portion is configured of a metal layer and a part of a wiring having a damascene structure.

[A16]

The magnetoresistive element as described in any of [A01] to [A12], wherein

the layered structure is surrounded by an insulating layer;
the metal layer is formed on or above the layered structure and is connected to the layered structure; and
a wiring layer is formed on the metal layer.

### REFERENCE SIGNS LIST

10 Semiconductor substrate
11 Element separation region
12 Gate electrode (word line or address line)
13 Gate insulating layer
14 Channel forming region
15A, 15B Source/drain region
16 Gate sidewall
21,22 Interlayer insulating layer
23,24 Connection hole
31,32 Insulating layer
33, 33A, 33B Sidewall
41 First electrode
42 Second electrode
50 Layered structure
60, 70 Connection portion
61 Metal layer
61′ Ti layer
62 Contact hole portion
63, 73, 83 Second wiring (bit wire)
64 Metal layer
65 Connection hole
66, 76, 86 First wiring (sense wire)
67A, 67B Opening
68A, 68B Groove
100 Composite magnetic head
101 Magnetoresistive element
122 Substrate
123 Insulation layer
125 First magnetic shield layer
127 Second magnetic shield layer
128, 129 Bias layer
130, 131 Connection terminal
132 Upper layer core
133 Thin-film coil
TR Selection transistor

What is claimed is:

1. A magnetoresistive element having at least a layered structure composed of a magnetization fixed layer, an intermediate layer and a storage layer, wherein
a metal layer is formed on or above the layered structure;
an orthogonal projection image of the layered structure with respect to the metal layer is contained in the metal layer; and
assuming that an oxide formation Gibbs energy of a metal atom constituting the metal layer at a temperature T (° C.) of 0° C. or higher and 400° C. or lower is E_{Gib-0}(T), and a minimum Gibbs energy among oxide formation Gibbs energies of metal atoms constituting the magnetization fixed layer and the storage layer at the temperature T is E_{Gib-1}(T),
E_{Gib-0}(T)<E_{Gib-1}(T) (1)
is satisfied.

2. The magnetoresistive element according to claim 1, wherein
assuming that a maximum Gibbs energy among oxide formation Gibbs energies of metal atoms constituting the intermediate layer at the temperature T is E_{Gib-2}(T),
E_{Gib-2}(T)<E_{Gib-0}(T)
is satisfied.

3. A magnetoresistive element having at least a layered structure composed of a magnetization fixed layer, an intermediate layer and a storage layer, wherein
a metal layer is formed on or above the layered structure;
an orthogonal projection image of the layered structure with respect to the metal layer is contained in the metal layer; and
assuming that an oxide formation Gibbs energy of a metal atom constituting the metal layer at a temperature T (° C.) of 0° C. or higher and 400° C. or lower is E_{Gib-0}(T), and a maximum Gibbs energy among oxide formation Gibbs energies of metal atoms constituting the intermediate layer at the temperature T is E_{Gib-2}(T),
E_{Gib-2}(T)≤E_{Gib-0}(T) (2)
is satisfied.

4. The magnetoresistive element according to claim 1, wherein the metal layer includes at least one metal atom selected from the group consisting of a titanium atom, an aluminum atom, and a magnesium atom.

5. The magnetoresistive element according to claim 1, wherein a metal atom constituting the magnetization fixed layer and the storage layer includes a cobalt atom, or an iron atom, or a cobalt atom and an iron atom.

6. The magnetoresistive element according to claim 1, wherein a metal atom constituting the intermediate layer includes a magnesium atom or an aluminum atom.

7. The magnetoresistive element according to claim 1, wherein a metal atom constituting the metal layer is contained in the metal layer at 60 atomic % or more.

8. The magnetoresistive element according to claim 1, wherein the thickness of the metal layer is 1×10⁻⁸ m or more.

9. The magnetoresistive element according to claim 1, wherein a side surface of the layered structure is covered with a sidewall.

10. The magnetoresistive element according to claim 9, wherein
assuming that an oxide formation Gibbs energy of a metal atom constituting the sidewall at the temperature T is E_{Gib-SW}(T),
E_{Gib-2}(T)≤E_{Gib-SW}(T)<E_{Gib-1}(T)
is satisfied.

11. The magnetoresistive element according to claim 9, wherein an atom constituting the sidewall comprises at least one kind of atom selected from the group consisting of titanium, aluminum, magnesium, and silicon.

12. The magnetoresistive element according to claim 9, wherein at least a part of the sidewall is covered with a metal layer.

13. The magnetoresistive element according to claim 1, wherein
the layered structure is surrounded by an insulating layer;
a connection portion connected to the layered structure is formed on or above the layered structure; and
the metal layer is formed on an inner wall of the connection portion.

14. The magnetoresistive element according to claim 13, wherein the connection portion is configured of a metal layer and a contact hole portion.

15. The magnetoresistive element according to claim 13, wherein the connection portion is configured of a metal layer and a part of a wiring having a damascene structure.

16. The magnetoresistive element according to claim 1, wherein
the layered structure is surrounded by an insulating layer;
the metal layer is formed on or above the layered structure and is connected to the layered structure; and
a wiring layer is formed on the metal layer.
